(19) United States
(12) Patent Application Publication
(10) Pub. No.: US 2015/0381210 A1
(43) Pub. Date: Dec. 31, 2015

(54) PARITY CHECK MATRIX CREATION METHOD, ENCODING APPARATUS, AND RECORDING/REPRODUCTION APPARATUS

(71) Applicant: KABUSHIKI KAISHA TOSHIBA, Minato-ku (JP)

(72) Inventors: Kazuaki DOI, Kawasaki (JP); Akihito OGAWA, Fujisawa (JP)

(73) Assignee: KABUSHIKI KAISHA TOSHIBA, Minato-ku (JP)

(21) Appl. No.: 14/847,851

(22) Filed: Sep. 8, 2015

Related U.S. Application Data
(63) Continuation of application No. PCT/JP2013/057555, filed on Mar. 15, 2013.

(51) Int. Cl. H03M 13/00

(52) U.S. Cl. CPC H03M 13/616

(57) ABSTRACT

According to an embodiment, in a parity check matrix creation method, all of N column vectors in the mask matrix are different from each other. The B₁ first correction rows have at least one “1” in total in each of A₁ first correction columns. Each of the Bᵢ ith correction rows has at least one “1” in total in Aᵢ₋₁ (i−1)th correction columns. Each of the Bᵢ ith correction rows has “1” in one of Aᵢ ith correction columns included in a column set excluding the first correction column to an (i−1)th correction column. The Bᵢ ith correction rows include at least one “1” in total in each of the Aᵢ ith correction columns. A sum from B₁ to B_{I-1} equals a sum of S and a sum from A₁ to A_{I-1}.

### CROSS-REFERENCE TO RELATED APPLICATIONS

This application is a Continuation Application of PCT Application No. PCT/JP2013/057555, filed Mar. 15, 2013, the entire contents of which are incorporated herein by reference.

### FIELD

Embodiments described herein relate generally to an error correcting code.

### BACKGROUND

In recent years, recording media are increasing in capacity. As the capacities of recording media increase, the reproduction environment becomes stricter. For example, an optical recording medium achieves a large capacity by improving the line density of record marks, forming an information recording layer having a multilayer structure, and the like. On the other hand, reproduced data readily includes errors, resulting in deterioration of the reproduction environment. Hence, there is demanded a signal processing technique capable of accurately reconstructing reproduced data even under such a reproduction environment.

There have been proposed various kinds of error correcting code methods to correct errors in data in recording/reproduction systems and communication systems. An LDPC (Low Density Parity Check) code is known to have an excellent error correcting capability. In particular, the LDPC code exhibits an outstanding characteristic for random errors. However, the LDPC code does not necessarily exhibit a satisfactory characteristic for a burst error (continuous errors) that occurs due to defects in a recording medium or the like, and a composite error of a burst error and a random error. For this reason, when applying the LDPC code to a recording/reproduction system especially, the resistance to a burst error and a composite error of a burst error and a random error is demanded to be improved while suppressing degradation in the resistance to a random error.

### BRIEF DESCRIPTION OF THE DRAWINGS

FIG. 1 is a view showing a parity check matrix of an LDPC code.

FIG. 2 is an explanatory view of a technique of evaluating the resistance of an LDPC code corresponding to the parity check matrix shown in FIG. 1 to a burst error;

FIG. 3 is an explanatory view of a technique of evaluating the resistance of an LDPC code corresponding to the parity check matrix shown in FIG. 1 to a burst error.

FIG. 4 is an explanatory view of a technique of evaluating the resistance of an LDPC code corresponding to the parity check matrix shown in FIG. 1 to a burst error.

FIG. 5 is an explanatory view of a technique of evaluating the resistance of an LDPC code corresponding to the parity check matrix shown in FIG. 1 to a burst error.

FIG. 6 is an explanatory view of a technique of evaluating the resistance of an LDPC code corresponding to the parity check matrix shown in FIG. 1 to a burst error.

FIG. 7 is an explanatory view of a technique of evaluating the resistance of an LDPC code corresponding to the parity check matrix shown in FIG. 1 to a burst error.

FIG. 8 is an explanatory view of a technique of evaluating the resistance of an LDPC code corresponding to the parity check matrix shown in FIG. 1 to a burst error.

FIG. 9 is an explanatory view of a technique of evaluating the resistance of an LDPC code corresponding to the parity check matrix shown in FIG. 1 to a burst error.

FIG. 10 is an explanatory view of the resistance of an LDPC code corresponding to a mask matrix according to the first comparative example to a plurality of burst errors.

FIG. 11 is an explanatory view of the relationship between the number of correction rows and the number of correction columns in the mask matrix according to the first comparative example.

FIG. 12 is an explanatory view of the resistance of an LDPC code corresponding to a mask matrix according to the second comparative example to a composite error of a burst error and a random error.

FIG. 13 is an explanatory view of the resistance of an LDPC code corresponding to a mask matrix according to the second comparative example to a composite error of a burst error and a random error.

FIG. 14 is an explanatory view of the resistance of an LDPC code corresponding to a mask matrix according to the second comparative example to a composite error of a burst error and a random error.

FIG. 15 is an explanatory view of the resistance of an LDPC code corresponding to a mask matrix according to the second comparative example to a composite error of a burst error and a random error.

FIG. 16 is an explanatory view of the resistance of an LDPC code according to the first embodiment to a composite error of a burst error and a random error.

FIG. 17 is an explanatory view of the resistance of an LDPC code according to the first embodiment to a composite error of a burst error and a random error.

FIG. 18 is an explanatory view of the resistance of an LDPC code according to the first embodiment to a composite error of a burst error and a random error.

FIG. 19 is an explanatory view of the resistance of an LDPC code according to the first embodiment to a composite error of a burst error and a random error.

FIG. 20 is an explanatory view of a simulation of iterated decoding for an LDPC code corresponding to a parity check matrix having the same structure as a mask matrix shown in FIG. 16.

FIG. 21 is an explanatory view of a simulation of iterated decoding for an LDPC code corresponding to a parity check matrix having the same structure as a mask matrix shown in FIG. 16.

FIG. 22 is an explanatory view of a simulation of iterated decoding for an LDPC code corresponding to a parity check matrix having the same structure as a mask matrix shown in FIG. 16.

FIG. 23 is an explanatory view of a simulation of iterated decoding for an LDPC code corresponding to a parity check matrix having the same structure as a mask matrix shown in FIG. 16.

FIG. 24 is an explanatory view of a simulation of iterated decoding for an LDPC code corresponding to a parity check matrix having the same structure as a mask matrix shown in FIG. 16.

FIG. 25 is an explanatory view of design of a mask matrix.

FIG. 26 is an explanatory view of design of a mask matrix.

FIG. 27 is an explanatory view of design of a mask matrix.

FIG. 28 is an explanatory view of design of a mask matrix.

FIG. 29 is an explanatory view of design of a mask matrix.

FIG. 30 is a flowchart showing processing of creating the initial matrix of a mask matrix.

FIG. 31 is an explanatory view of processing of creating the initial matrix of a mask matrix.

FIG. 32 is an explanatory view of processing of creating the initial matrix of a mask matrix.

FIG. 33 is an explanatory view of processing of creating the initial matrix of a mask matrix.

FIG. 34 is an explanatory view of processing of creating the initial matrix of a mask matrix.

FIG. 35 is an explanatory view of processing of creating the initial matrix of a mask matrix.

FIG. 36 is an explanatory view of processing of creating the initial matrix of a mask matrix.

FIG. 37 is an explanatory view of processing of creating the initial matrix of a mask matrix.

FIG. 38 is a flowchart showing processing of creating a mask matrix.

FIG. 39 is an explanatory view of the resistance of an LDPC code corresponding to a mask matrix created by a parity check matrix creation method according to the first embodiment to a plurality of burst errors.

FIG. 40 is an explanatory view of a simulation condition of the resistance of an LDPC code according to the first embodiment to a composite error of a random error and a burst error.

FIG. 41 is an explanatory view of a simulation condition of the resistance of an LDPC code according to the first embodiment to a composite error of a random error and a burst error.

FIG. 42 is an explanatory view of a simulation condition of the resistance of an LDPC code according to the first embodiment to a composite error of a random error and a burst error.

FIG. 43A is a view showing a parity check matrix according to the third comparative example.

FIG. 43B is a view showing a parity check matrix according to the third comparative example.

FIG. 44A is a view showing a parity check matrix created by the parity check matrix creation method according to the first embodiment.

FIG. 44B is a view showing a parity check matrix created by the parity check matrix creation method according to the first embodiment.

FIG. 45A is a view showing a parity check matrix created by the parity check matrix creation method according to the first embodiment.

FIG. 45B is a view showing a parity check matrix created by the parity check matrix creation method according to the first embodiment.

FIG. 46A is a view showing a parity check matrix created by the parity check matrix creation method according to the first embodiment.

FIG. 46B is a view showing a parity check matrix created by the parity check matrix creation method according to the first embodiment.

FIG. 47A is a view showing a parity check matrix created by the parity check matrix creation method according to the first embodiment.

FIG. 47B is a view showing a parity check matrix created by the parity check matrix creation method according to the first embodiment.

FIG. 48A is a view showing a parity check matrix created by the parity check matrix creation method according to the first embodiment.

FIG. 48B is a view showing a parity check matrix created by the parity check matrix creation method according to the first embodiment.

FIG. 49 is a graph showing a simulation result of the resistance of the LDPC code according to the first embodiment to a composite error of a random error and a burst error.

FIG. 50 is a block diagram showing a recording/reproduction apparatus according to the second embodiment.

FIG. 51 is a block diagram showing an encoding processing unit of the recording/reproduction apparatus according to the second embodiment.

FIG. 52 is a view showing the format of composed data of user code data, BIS data, and SYNC data.

FIG. 53 is a block diagram showing a reproduction processing unit of the recording/reproduction apparatus according to the second embodiment.

FIG. 54 is an explanatory view of a technique of estimating a burst occurrence area under the format shown in FIG. 52.

### DETAILED DESCRIPTION

Embodiments will now be described with reference to the accompanying drawings.

According to an embodiment, a parity check matrix creation method includes creating a mask matrix whose column weight is K (K is an integer not less than 2) by assigning one of “1” and “0” to each element of M rows×N columns (M is an integer not less than 4, and N is an integer larger than M). The method further includes creating a parity check matrix by, for each element in the mask matrix, arranging a cyclic permutation matrix having P rows×P columns (P is an integer not less than 2) at a corresponding position when the element is “1” and arranging a zero matrix having P rows×P columns at a corresponding position when the element is “0”. All of N column vectors in the mask matrix are different from each other. A submatrix having M rows×L columns (L is an integer not more than (M−K+1−S) and S is an integer not less than 1) obtained by arbitrarily extracting L continuous columns from the mask matrix includes B₁ (B₁ is an integer not less than 1) first correction rows. The submatrix further includes Bᵢ (Bᵢ is an integer not less than 1, i is any integer not less than 2 and not more than I, and I is an integer not less than 2) ith correction rows. Each of the B₁ first correction rows has a row weight of 1. The B₁ first correction rows have at least one “1” in total in each of A₁ (A₁ is an integer not less than 1) first correction columns. Each of the Bᵢ ith correction rows has a row weight of not less than 2. Each of the Bᵢ ith correction rows has at least one “1” in total in Aᵢ₋₁ (Aᵢ₋₁ is an integer not less than 1 and not more than Bᵢ₋₁) (i−1)th correction columns. Each of the Bᵢ ith correction rows has “1” in one of Aᵢ (Aᵢ is an integer not less than 1 and not more than Bᵢ) ith correction columns included in a column set excluding the first correction column to the (i−1)th correction column. The Bᵢ ith correction rows include at least one “1” in total in each of the Aᵢ ith correction columns. A sum from A₁ to A_{I} equals L. Bᵢ is not more than Aᵢ₋₁×(K−1). A sum from B₁ to B_{I-1} equals a sum of S and a sum from A₁ to A_{I-1}.

Note that the same or similar reference numerals denote elements that are the same as or similar to those already explained, and a repetitive description will basically be omitted.

### First Embodiment

The first embodiment is directed to a method of creating a parity check matrix that defines an LDPC code having a satisfactory resistance to a composite error of a burst error and a random error.

The resistance of an LDPC code to a burst error can be evaluated based on a parity check matrix that defines the LDPC code, as will be described below.

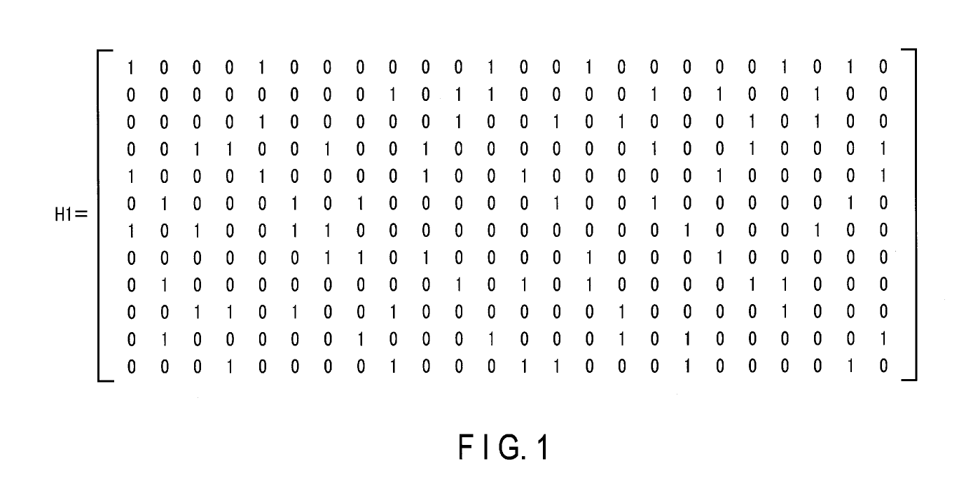

FIG. 1 shows a parity check matrix (H1). The parity check matrix (H1) defines an LDPC code having an information length of 12 bits, a parity length of 12 bits, and a code length of 24 bits. In the following description, code data is expressed by, for example, a format C=(c1, c2, . . . , c23, c24).

Basically, an LDPC code is decoded by iterating correction processing on a row basis based on a result of parity check and propagation processing of propagating the correction result of each row in the row direction. Rows (that is, check nodes) and columns (that is, variable nodes) corresponding to elements “1” of a parity check matrix are involved in the correction processing and the propagation processing.

For example, according to the parity check matrix (H1), the first, fifth, 12th, 15th, 21st, and 23rd columns (that is, c1, c5, c12, c15, c21, and c23) of the first row are the subjects of correction processing. The subjects of correction processing in other rows are also decided in the same way as described above. According to the parity check matrix (H1), the correction result of the first column (that is, cl) of the first row propagates to the fifth and seventh rows, and the correction result of the first columns of the fifth and seventh rows propagates to the first row. Other correction results also propagate in the same way as described above.

Assume that a burst error occurs from the first bit (c1) up to the eighth bit (c8) of the LDPC code defined by the parity check matrix (H1), and no error occurs in the remaining bits. In this case, whether the burst error is correctable can be determined based on column vectors from the first column up to the eighth column of the parity check matrix (H1).

More specifically, as shown in FIG. 2, a submatrix (Hsub_1) formed from the column vectors from the first column up to the eighth column of the parity check matrix (H1) can be extracted from the parity check matrix (H1). Focusing on the matrix (Hsub_1), the first and fifth bits of the first row are the subjects of correction processing. In the remaining rows as well, bits corresponding to columns with “1” are the subjects of correction processing.

In the following description, elements of columns that are not the subjects of correction processing in the rows of the matrix (Hsub_1) will be expressed as “—”, and elements of columns that are the subjects of correction processing will be expressed as “⊚”, “⋄”, “◯”, “♦”, or “×”.

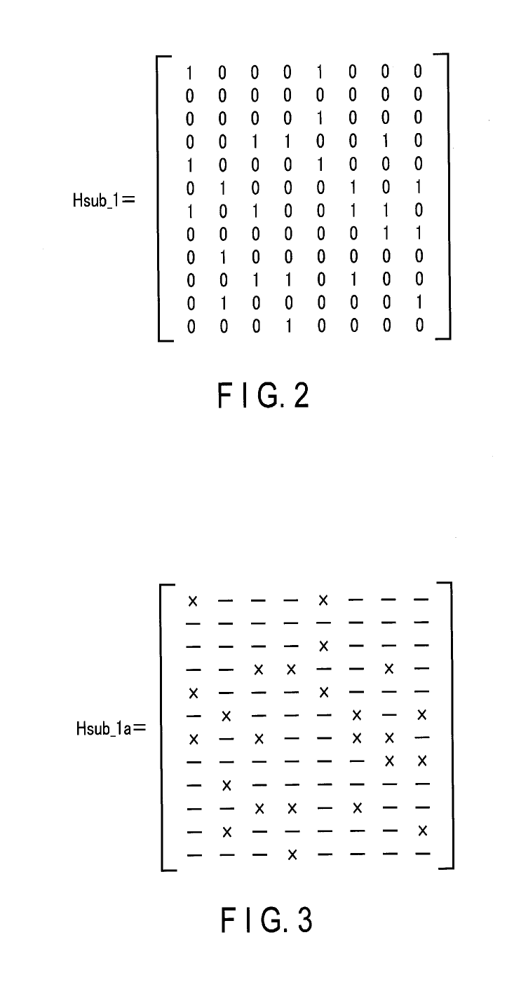

Symbol “⊚” indicates that the error is corrected for the first time by correction processing (to be also referred to as row processing) of the ith time (i is the number of times of iterated decoding (that is, correction processing and propagation processing)), and symbol “⋄” indicates that the error was corrected by correction processing before the correction processing of the ith time. Symbol “◯” indicates that the correction result is propagated for the first time by propagation processing (to be also referred to as column processing) of the ith time. Symbol “♦” indicates that the correction result was propagated by propagation processing before the propagation processing of the ith time. Symbol “×” indicates that the error is not corrected. At the start of correction processing of the first time, the burst error that has occurred from the first column up to the eighth column is not corrected. Hence, a matrix (Hsub_1a) shown in FIG. 3 is obtained.

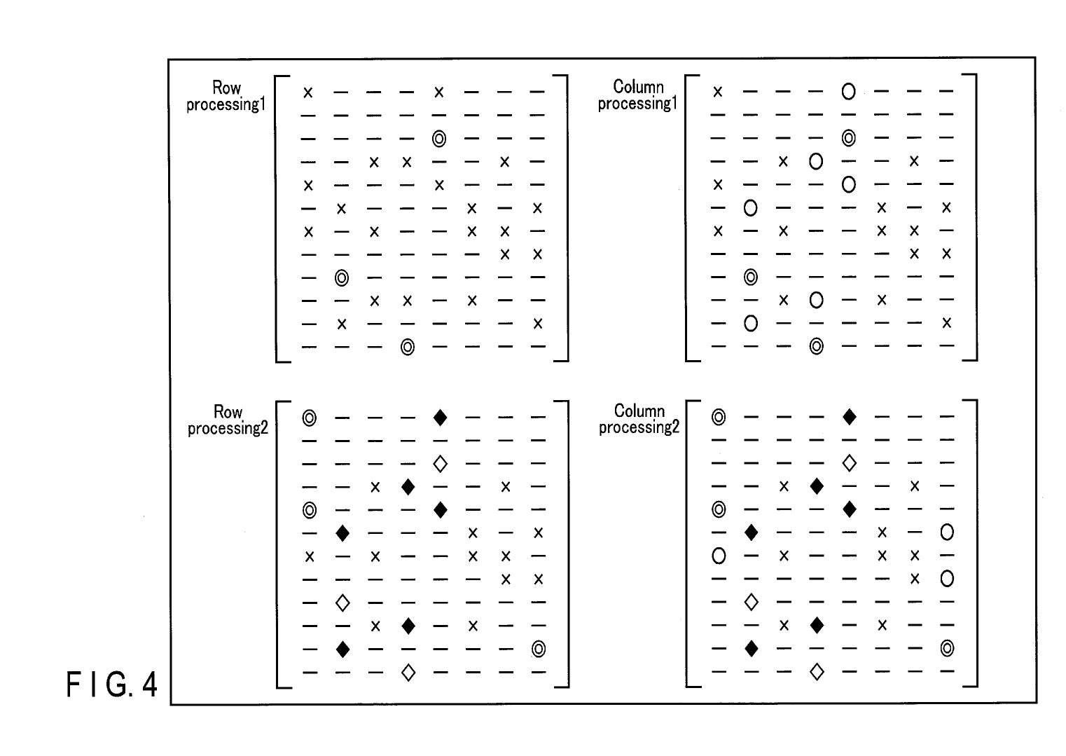

On the principle of LDPC code, when one error bit is included in a row of interest, the error can be corrected at a time by correction processing on the row basis. However, when two or more error bits are included in the row of interest, the errors cannot be corrected at a time. For this reason, in the third, ninth, and 12th rows each including one uncorrected bit out of the subjects of correction processing, the uncorrected bits are corrected by the correction processing of the first time. However, in the remaining rows each including two or more uncorrected bits out of the subjects of correction processing, the uncorrected bits are not corrected. Hence, a matrix labeled “row processing 1” in FIG. 4 is obtained as the result of the correction processing of the first time.

As described above, according to propagation processing, the correction result of each row propagates in the row direction. More specifically, the fifth column of the third row, the second column of the ninth row, and the fourth column of the 12th row are corrected by the correction processing of the first time. The correction result of the fifth column of the third row propagates to the first and fifth rows in which the fifth column is likewise the subject of correction processing. The other correction results also propagate similarly. Hence, a matrix labeled “column processing 1” in FIG. 4 is obtained as the result of propagation processing of the first time.

As indicated by the matrix labeled “column processing 1” in FIG. 4, the number of uncorrected bits out of the subjects of correction processing in each of the first, fifth, and 11th rows decreases from 2 to 1 at the start of correction processing of the second time. For this reason, the uncorrected bits in the first, fifth, and 11th rows are corrected by the correction processing of the second time. That is, a matrix labeled “row processing 2” in FIG. 4 is obtained.

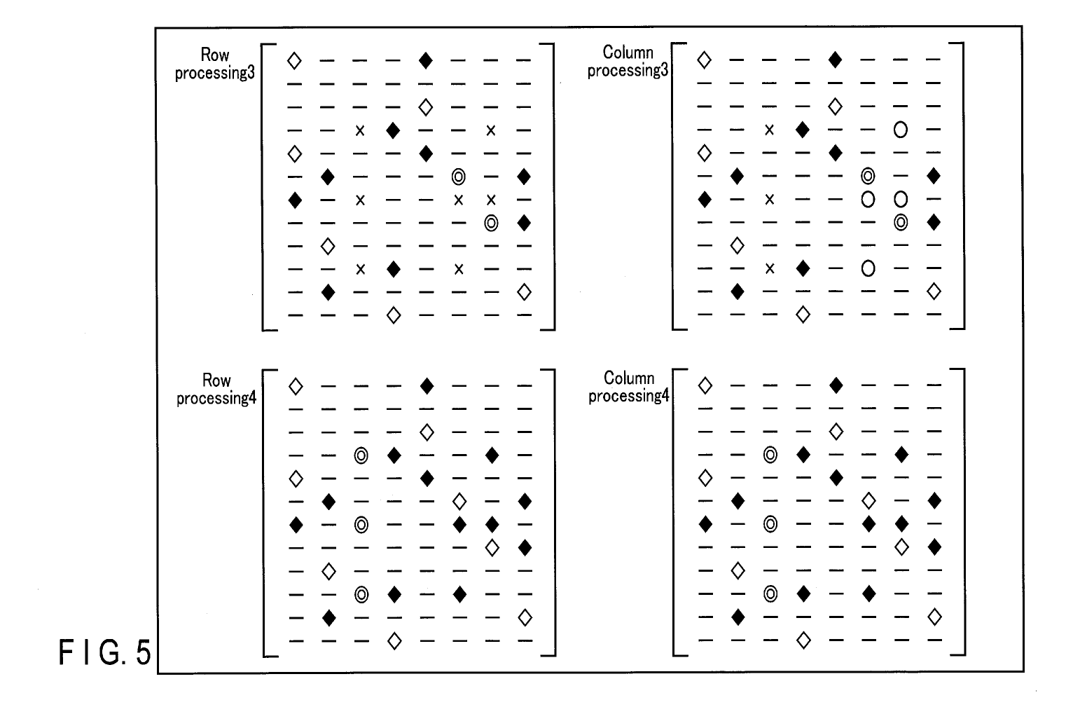

Subsequent correction processing and propagation processing progress is as shown in FIGS. 4 and 5. As indicated by a matrix labeled “column processing 4” in FIG. 5, the burst error is completely corrected at the end of propagation processing of the fourth time. Hence, according to the parity check matrix (H1), the burst error can be corrected unless an error has occurred in a bit other than the first bit (c1) to the eighth bit (c8) where the burst error has occurred.

In the following description, terms “ith correction row” and “ith correction column” are used for descriptive convenience. The “ith correction row” means a row in which all uncorrected bits are corrected for the first time by ith row processing (correction processing). The “ith correction column” means a column corrected by ith column processing (correction processing) based on the “ith correction row”.

For example, the rows and columns of the above-described matrix (Hsub_1) can be expressed as shown in FIG. 6 using “correction rows” and “correction columns”. As indicated by the matrix labeled “row processing 1” in FIG. 4, all uncorrected bits in the third, ninth, and 12th rows are corrected for the first time by the correction processing of the first time. Hence, these rows can be classified into first correction rows. The second, fourth, and fifth columns are corrected by the correction processing of the first time based on the ith correction rows. Hence, these columns can be classified into the first correction columns. The remaining rows (except the second row) and columns can similarly be classified into the ith correction rows and the ith correction columns.

Next, assume that a burst error occurs from the 16th bit (c16) up to the 23rd bit (c23) of the LDPC code defined by the parity check matrix (H1), and no error occurs in the remaining bits. In this case, whether the burst error is correctable can be determined based on column vectors from the 16th column up to the 23rd column of the parity check matrix (H1).

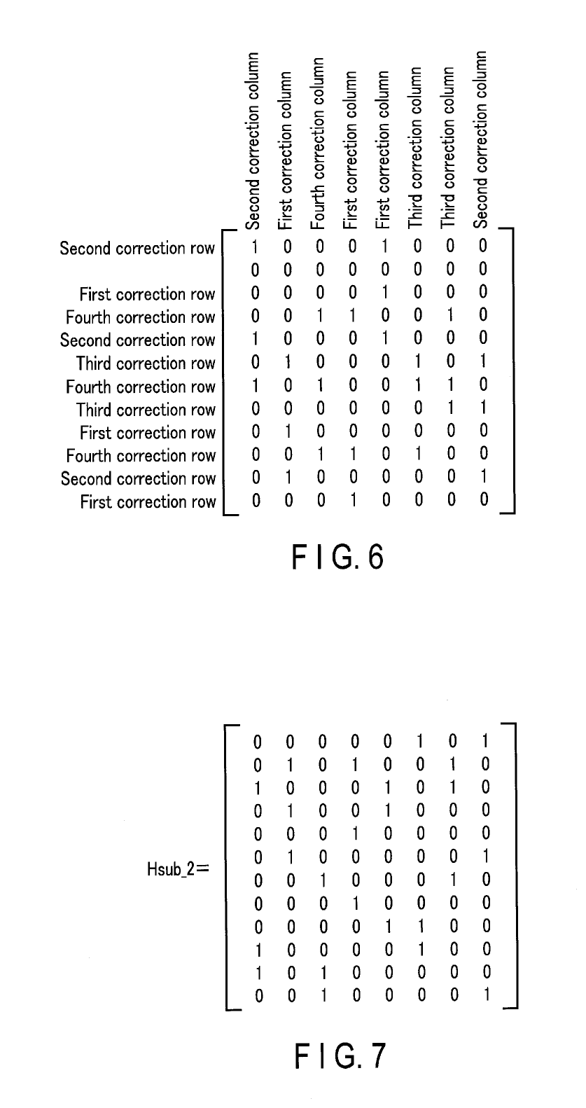

More specifically, as shown in FIG. 7, a submatrix (Hsub_2) formed from the column vectors from the 16th column up to the 23rd column of the parity check matrix (H1) can be extracted from the parity check matrix (H1).

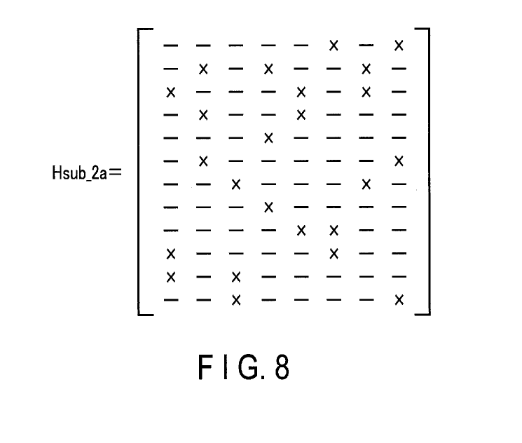

In the following description, elements of columns that are not the subjects of correction processing in the rows of the matrix (Hsub_2) will be expressed as “—”, and elements of columns that are the subjects of correction processing will be expressed as “⊚”, “⋄”, “◯”, “♦”, or “×”, as in the example of the matrix (Hsub_1). Since the burst error that has occurred from the 16th bit up to the 23rd bit is not corrected at the start of the correction processing of the first time, a matrix (Hsub_2a) shown in FIG. 8 is obtained.

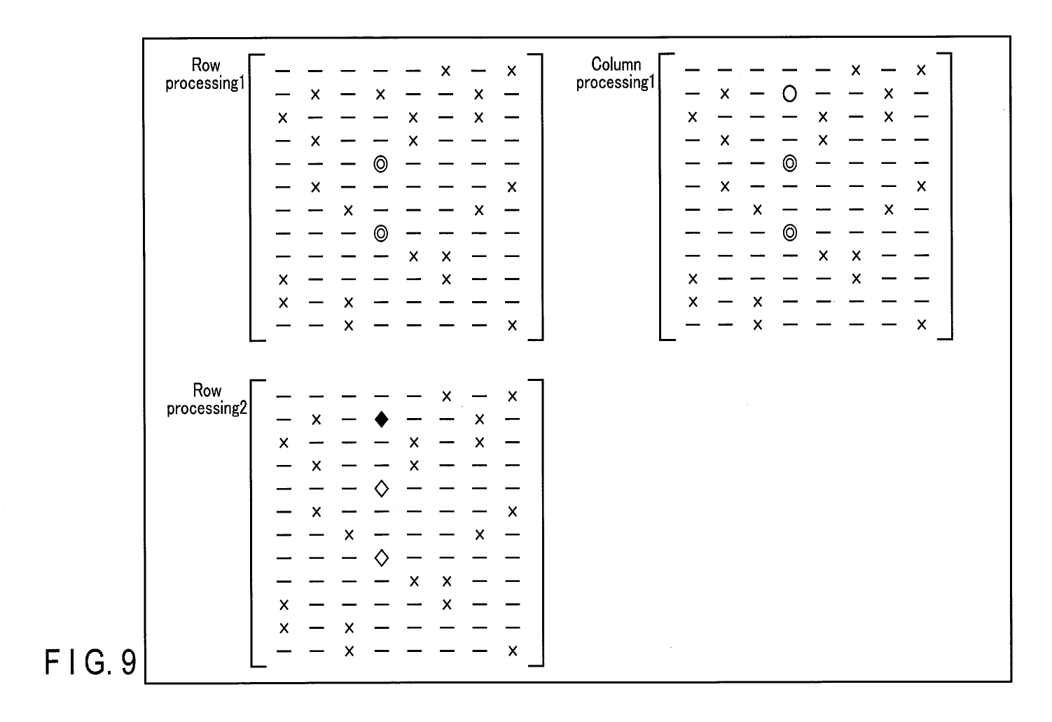

According to the correction processing of the first time, in the fifth and eighth rows each including one uncorrected bit out of the subjects of correction processing, the uncorrected bits are corrected. However, in the remaining rows each including two or more uncorrected bits out of the subjects of correction processing, the uncorrected bits are not corrected. Hence, a matrix labeled “row processing 1” in FIG. 9 is obtained as the result of the correction processing of the first time.

The 19th columns of the fifth and eighth rows are corrected by the correction processing of the first time. The correction result of the 19th columns of the fifth and eighth rows propagates to the second row in which the 19th column is likewise the subject of correction processing. Hence, a matrix labeled “column processing 1” in FIG. 9 is obtained as the result of propagation processing of the first time.

On the principle of LDPC code, if a row including two or more uncorrected bits out of the subjects of correction processing remains, and any row including one uncorrected bit out of the subjects of correction processing does not remain at the start of correction processing of the (i+1)th time, the error cannot be corrected even by correction processing and propagation processing of the (i+1)th and subsequent times. As indicated by the matrix labeled “column processing 1” in FIG. 9, the number of uncorrected bits out of the subjects of correction processing in the second row decreases from 3 to 2 at the start of correction processing of the second time. However, in rows other than the fifth and eighth rows, the number of uncorrected bits out of the subjects of correction processing still remains 2 or more, and there is no row including one uncorrected bit out of the subjects of correction processing. For this reason, the 16th to 18th bits, and the 20th to 23rd bits cannot be corrected even by further iterating correction processing and propagation processing. Hence, according to the parity check matrix (H1), if a burst error occurs from the 16th bit (c16) up to the 23rd bit (c23) of code data, the burst error cannot be corrected.

When a submatrix corresponding to an assumed burst error is extracted from a parity check matrix and analyzed, the resistance of an LDPC code defined by the parity check matrix to the burst error can be evaluated. Note that assuming a burst error means defining the number of generated burst errors, the burst error occurrence area and burst error occurrence scale.

It is not easy to design an LDPC code that stably exhibits a high resistance to a burst error that can occur on various scales in various areas. Regarding this problem, a related art 1 (William E. Ryan and Shu Lin, “Channel Codes Classical and Modern”) proposes a technique of designing a quasi-cyclic LDPC code guaranteed to be able to correct a burst error up to at least (M−K)×P+1 bits when the number of generated burst errors is 1, where M is the row size of a mask matrix to be described later, K is the column weight of the mask matrix, and P is the size of a block matrix corresponding to the elements of the mask matrix.

The mask matrix represents the structure of a corresponding parity check matrix. More specifically, the parity check matrix arranges block matrices in number corresponding to the row size in the row direction and block matrices in number corresponding to the column size in the column direction. Each block matrix is a cyclic permutation matrix having P rows×P columns or a zero matrix having P rows×P columns. Each element in the mask matrix represents whether each block matrix in the parity check matrix is the cyclic permutation matrix or zero matrix.

For example, the mask matrix has “1” or “0” as an element. “1” represents that the corresponding block matrix in the parity check matrix is a cyclic permutation matrix. “0” represents that the corresponding block matrix in the parity check matrix is a zero matrix. That is, a block matrix having P rows×P columns including the element of the ((m−1)×P+1)th row and the ((n−1)×P+1)th column of the parity check matrix is a cyclic permutation matrix when the element of the mth row and the nth column of the mask matrix is “1” or a zero matrix when the element is “0”.

The mask matrix can be derived by connecting submatrices (G) each having M rows×M columns to be described later in an arbitrary connection number in the column direction, as indicated by

Z1=[GG . . . GG] (1)

In equation (1), Z1 represents the mask matrix. When, for example, M=8 and K=4, the submatrix (G) can be derived by

$$G = ( \begin{matrix}1 & 0 & 0 & 0 & 0 & 1 & 1 & 1 \\ 1 & 1 & 0 & 0 & 0 & 0 & 1 & 1 \\ 1 & 1 & 1 & 0 & 0 & 0 & 0 & 1 \\ 1 & 1 & 1 & 1 & 0 & 0 & 0 & 0 \\ 0 & 1 & 1 & 1 & 1 & 0 & 0 & 0 \\ 0 & 0 & 1 & 1 & 1 & 1 & 0 & 0 \\ 0 & 0 & 0 & 1 & 1 & 1 & 1 & 0 \\ 0 & 0 & 0 & 0 & 1 & 1 & 1 & 1\end{matrix} ) \qquad ( 2 )$$

An LDPC code corresponding to the mask matrix derived by equations (1) and (2) can correct a burst error over five blocks when the number of generated burst errors is 1 according to the above-described evaluation technique. More specifically, when the number of connected submatrices (G) in the mask matrix (Z1) is 8, the coding rate of the LDPC code is 7/8 (=(8M−M)/8M). In addition, when the size (P) of the block matrix is 72, the LDPC code is guaranteed to be able to correct a burst error of 289 (=(8−4)×72+1) bits when the number of generated burst errors is 1.

When the mask matrix (Z1) of equation (1) is generalized, a mask matrix (Z2) represented by equation (3) is obtained. The mask matrix (Z2) is derived by connecting submatrices (Ga) each having M rows×M columns to be described later in an arbitrary connection number in the column direction. In the following explanation, the mask matrix (Z1 or Z2) represented by equation (1) or (3) will be referred to as a mask matrix according to the first comparative example.

Z2=[GaGa . . . GaGa] (3)

The submatrix (Ga) of equation (3) is formed from a first block matrix (G_{L}) having K rows×K columns, a second block matrix (G_{U}) having K rows×K columns, and a zero matrix having K rows×K columns, as indicated by

$$Ga = ( \begin{matrix}{G}_{L} & 0 & … & 0 & 0 & {G}_{U} \\ {G}_{U} & {G}_{L} & ⋱ & ⋮ & ⋮ & 0 \\ 0 & {G}_{U} & ⋱ & 0 & ⋮ & ⋮ \\ ⋮ & 0 & ⋱ & {G}_{L} & 0 & ⋮ \\ ⋮ & ⋮ & ⋱ & {G}_{U} & {G}_{L} & 0 \\ 0 & 0 & … & 0 & {G}_{U} & {G}_{L}\end{matrix} ) \qquad ( 4 )$$

The first block matrix (G_{L}) in equation (4) is represented by

$${G}_{L} = ( \begin{matrix}1 & 0 & … & 0 \\ ⋮ & 1 & ⋱ & ⋮ \\ ⋮ & ⋮ & ⋱ & 0 \\ 1 & 1 & … & 1\end{matrix} ) \qquad ( 5 )$$

and the second block matrix (G_{U}) is represented by

$${G}_{U} = ( \begin{matrix}0 & 1 & … & 1 \\ ⋮ & 0 & ⋱ & ⋮ \\ ⋮ & ⋮ & ⋱ & 1 \\ 0 & 0 & … & 0\end{matrix} ) \qquad ( 6 )$$

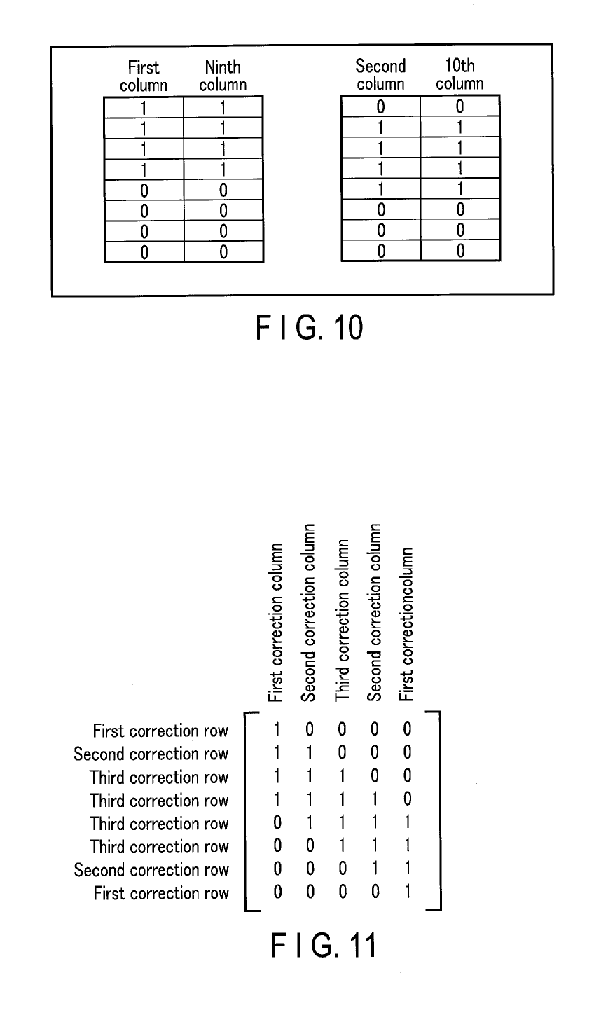

Each mask matrix according to the first comparative example is formed by connecting a plurality of submatrices (G or Ga). For this reason, in these mask matrices, the same column vectors appear at a predetermined period according to the row size of the mask matrices. For example, in the mask matrix (Z1) represented by equation (1), the same column vectors appear every eight columns, as shown in FIG. 10, because the row size=8.

Hence, if the number of generated burst errors is 2 or more, each mask matrix according to the first comparative example may be unable to correct these burst errors regardless of the number of generated burst errors and the scale of each burst error. For example, assume that a first burst error occurs in an area including the first, . . . , Pth bits corresponding to the first column of the mask matrix (Z1), and a second burst error occurs in an area including the (8P+1)th, . . . , (9P)th bits corresponding to the ninth column. In this case, when performing correction processing of the first time, a row including two or more uncorrected bits out of the subjects of correction processing remains, and no row including one uncorrected bit out of the subjects of correction processing remains. It is therefore impossible to correct the errors even by the correction processing and propagation processing of the first and subsequent times.

That is, if a column vector corresponding to the occurrence area of a given burst error matches a column vector corresponding to the occurrence area of another burst error in the mask matrix, these burst errors cannot be corrected. In each mask matrix according to the first comparative example, the number of times of appearance of the same column vector increases as the number of connected submatrices increases. Hence, the higher the coding rate is designed to be, the larger the number of uncorrectable burst error patterns becomes. This degrades the resistance of the LDPC code to the burst errors.

In each mask matrix according to the first comparative example, a loop 4 that is a factor to degrade the performance of the LDPC code is readily generated. This is because the same column vector repetitively appears, and the number of overlaps of rows where the element “1” appears between adjacent column vectors is large (more specifically, K−1). The number of overlaps increases as the column weight of the mask matrix increases. That is, as the column weight of the mask matrix increases, many loops 4 are generated in the mask matrix.

According to the mask matrices of the first comparative example, when a burst error over L columns occurs, the burst error can sequentially be corrected on a column basis from both ends. In other words, two columns are corrected at maximum by one correction processing. For this reason, the number of iterated decoding processes (that is, the number of correction processes and propagation processes) necessary to correct a burst error over L columns is L/2 (rounded up when L is an odd number). That is, the necessary number of iterated decoding processes linearly increases with respect to the scale (L) of the burst error. Note that the related art 1 does not disclose a technique of creating a mask matrix capable of correcting errors in three or more columns by one correction processing.

Additionally, as a characteristic feature of the mask matrix of the first comparative example, the number of ith correction rows equals the number of ith correction columns concerning i=I−1. Note that I is the number of iteration processes necessary to correct a burst error. For example, the correction rows and correction columns of a parity check matrix having the same structure as a submatrix obtained by extracting the first to fifth columns out of the above-described submatrix (G) (here, M=8, and K=4) can be expressed as shown in FIG. 11. In the example of FIG. 11, I=3. The number of first correction rows (=2) equals the number of first correction columns (=2), and the number of second correction rows (=2) also equals the number of second correction columns (=2). According to an LDPC code corresponding to a parity check matrix having such a characteristic feature, if a composite error of a burst error and a random error occurs, error correction is difficult at a high possibility.

The resistance of a parity check matrix (H3) according to the second comparative example, which has the characteristic representing that the number of ith correction rows equals the number of ith correction columns concerning i=1, . . . , I−1, to a composite error of a burst error and a random error will be described below.

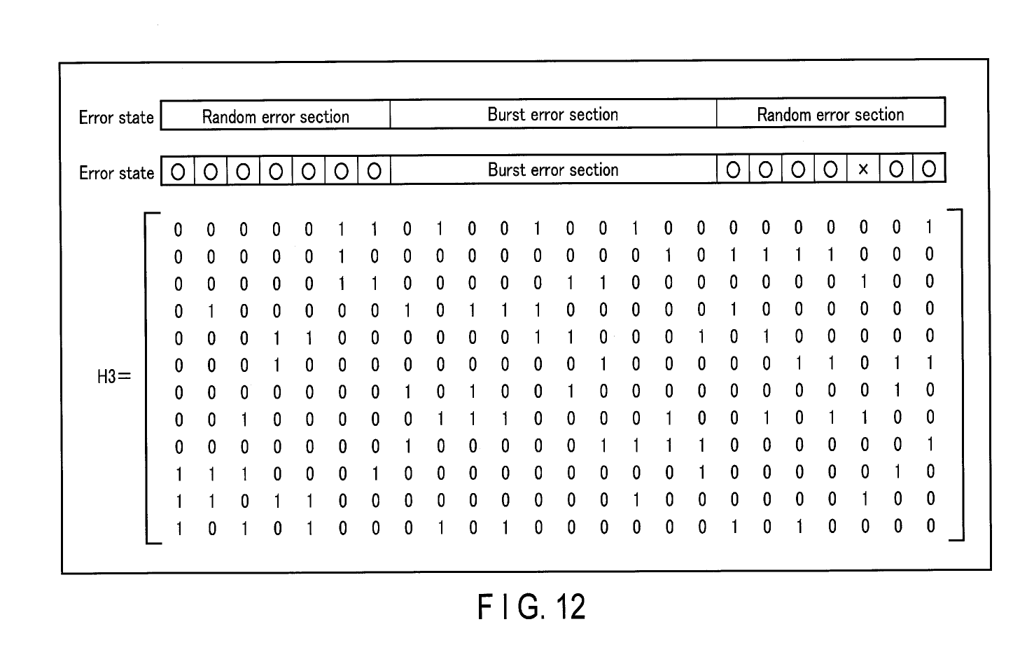

In the parity check matrix (H3), as shown in FIG. 12, the number of ith correction rows equals the number of ith correction columns concerning i=I−1, and all column vectors are different from each other. Assume that a burst error occurs in the eighth to 17th bits of an LDPC code defined by the parity check matrix (H3), and a random error occurs in the 22nd bit. In this case, whether the burst error is correctable can be determined based on column vectors from the eighth column up to the 17th column of the parity check matrix (H3).

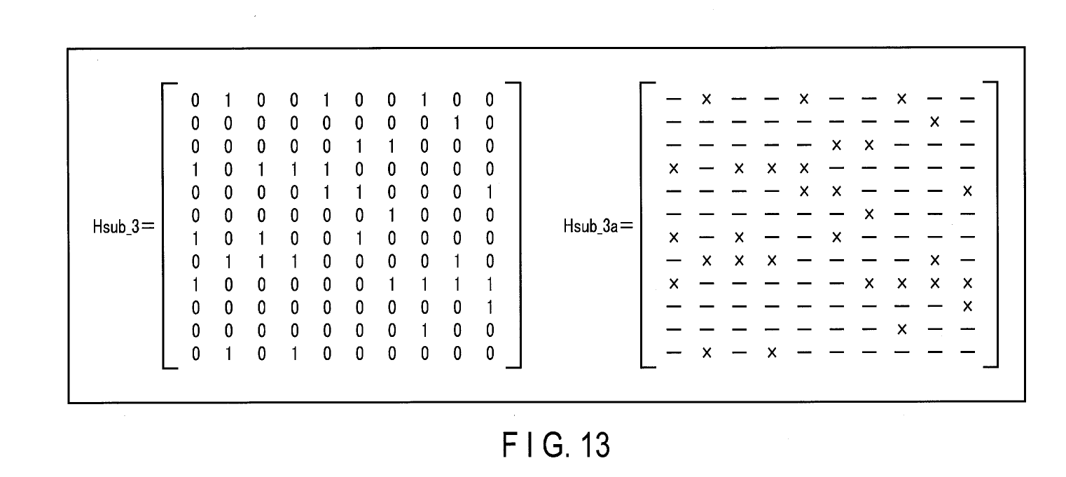

More specifically, as shown in FIG. 13, a submatrix (Hsub_3) formed from the column vectors from the eighth column up to the 17th column of the parity check matrix (H3) can be extracted from the parity check matrix (H3). Focusing on the matrix (Hsub_3), the ninth, 12th, and 15th columns of the first row are the subjects of correction processing. In the remaining rows as well, columns with “1” are the subjects of correction processing.

In the following description, elements of columns that are not the subjects of correction processing in the rows of the matrix (Hsub_3) will be expressed as “—”, and elements of columns that are the subjects of correction processing will be expressed as “⊚”, “⋄”, “◯”, “♦”, “×”, “Δ”, “▴”, “∇”, or “▾”. The meanings of symbols “⊚”, “⋄”, “◯”, “♦”, and “×” are the same as described above. Symbol “Δ” indicates that the error is corrected wrongly for the first time by correction processing of the ith time. Symbol “▴” indicates that the error was corrected wrongly by correction processing before the correction processing of the ith time. Symbol “∇” indicates that the correction result of “Δ” is propagated for the first time by propagation processing of the ith time. Symbol “▾” indicates that the correction result of “Δ” was propagated by propagation processing before the propagation processing of the ith time. At the start of correction processing of the first time, the burst error that has occurred from the eighth bit up to the 17th bit is not corrected. Hence, a matrix (Hsub_3a) shown in FIG. 13 is obtained.

In evaluation of the resistance to the burst errors in the above-described matrices (Hsub_1 and Hsub_2), nonoccurrence of a random error is assumed. Hence, at the end of correction processing of the ith time, all bits that are the subjects of correction processing can properly be corrected in the ith correction row. However, if a composite error of a burst error and a random error occurs, columns included in the burst error section may be corrected wrongly due to the influence of the random error. For example, the 22nd column of the parity check matrix (H3) has “1” in the third, eighth, and 11th rows. Hence, the columns to be corrected may be corrected wrongly by row processing of the third, eighth and 11th rows.

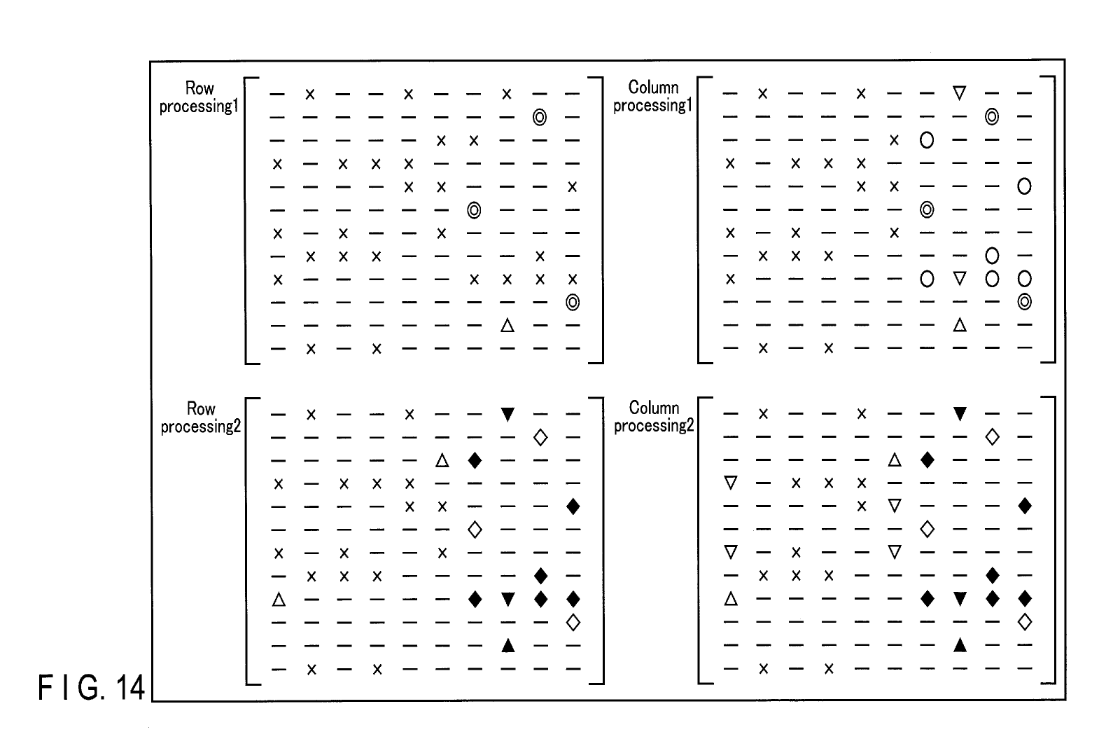

According to correction processing of the first time, the second, sixth, 10th, and 11th rows each including one uncorrected bit out of the subjects of correction processing are corrected. However, the 15th column of the 11th row is corrected wrongly due to the influence of the random error of the 22th column. Hence, a matrix labeled “row processing 1” in FIG. 14 is obtained as the result of the correction processing of the first time.

By the correction processing of the first time, the 16th column of the second row is properly corrected, the 14th column of the sixth row is properly corrected, the 17th column of the 10th row is properly corrected, and the 15th column of the 11th row is corrected wrongly. The correction result of the 16th column of the second row propagates to the eighth and ninth rows in which the 16th column is likewise the subject of correction processing. The other correction results also propagate similarly. Note that the wrong correction result of the 15th column of the 11th row propagates to the first and ninth rows in which the 15th column is likewise the subject of correction processing. Hence, a matrix labeled “column processing 1” in FIG. 14 is obtained as the result of propagation processing of the first time.

As indicated by the matrix labeled “column processing 1” in FIG. 14, the number of uncorrected bits out of the subjects of correction processing in each of the third and ninth rows decreases from 2 to 1 at the start of correction processing of the second time. For this reason, the third and ninth rows are corrected by the correction processing of the second time. However, the 13th column of the third row is corrected wrongly due to the influence of the random error of the 22th column. In addition, the eighth column of the ninth row is corrected wrongly due to the influence of the wrong correction of the 15th column by the propagation processing of the first time. Hence, a matrix labeled “row processing 2” in FIG. 14 is obtained as the result of the correction processing of the second time.

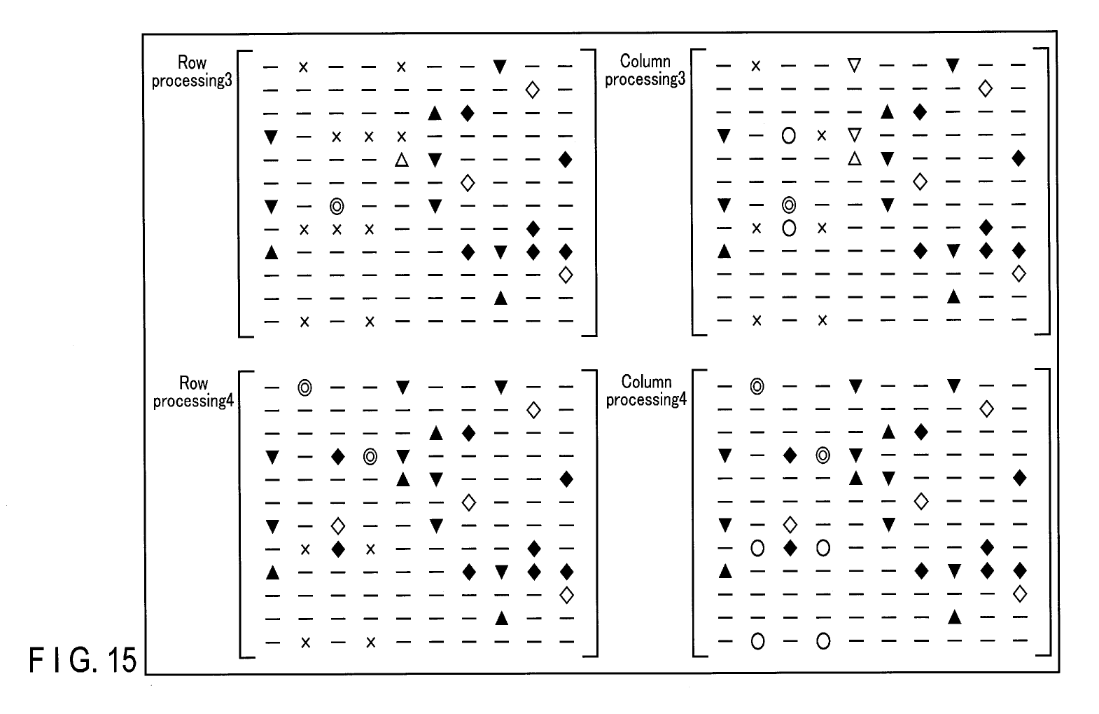

Subsequent correction processing and propagation processing progress is as shown in FIGS. 14 and 15. Note that columns to be corrected by the correction processing of the ith time out of the subjects of the correction processing of the ith time are corrected wrongly if the sum of the number of columns which are included in the subjects of the correction processing and to which wrong correction results have propagated and the number of columns in which random errors have occurred is an odd number, and corrected properly if the sum is an even number. For example, as indicated by a matrix labeled “row processing 3” in FIG. 15, the 10th column of the seventh row that is the third correction row is properly corrected because the number of columns (that is, the eighth and 13th columns) which are included in the subjects of the correction processing and to which wrong correction results have propagated is 2.

As indicated by a matrix labeled “column processing 4” in FIG. 15, although the burst error correction phase ends at the time of propagation processing of the fourth time (that is, D to be described later is corrected to a nonzero value for all bits in the burst error occurrence section), the eighth, 12th, 13th, and 15th bits are corrected wrongly (that is, the sign of D is wrong).

When the burst error correction phase ends, all bits have nonzero values as D. Hence, error correction for the bits in which random errors have occurred and the bits corrected wrongly in the burst error correction phase functions. However, if the number of error bits at this point of time exceeds the upper limit determined by the design of the parity check matrix (H3), error correction is impossible. Generally speaking, if a composite error of a burst error and a random error occurs in the LDPC code corresponding to the parity check matrix (H3), a wrong correction result occurs due to the influence of the random error in the burst error correction phase, and the wrong correction result propagates via column processing. As a result, it may be impossible to properly correct a sufficient number of bits in the burst error section, and error correction may be difficult.

Note that the above-described quasi-cyclic LDPC code also has the same problem. For example, assume that, concerning a mask matrix having the same structure as the parity check matrix (H3), a burst error occurs in bits corresponding to cyclic permutation matrices of the eighth to 17th columns, and a random error occurs in a bit corresponding to the cyclic permutation matrix of the 22nd column. In this case, correction processing and propagation processing of a quasi-cyclic LDPC code corresponding to the mask matrix progress in almost the same way as in FIGS. 14 and 15.

However, each “1” element of the mask matrix corresponds to a cyclic permutation matrix having P rows×P columns, and its shift amount does not necessarily match. Hence, strictly speaking, correction processing and propagation processing of the quasi-cyclic LDPC code may be different from FIGS. 14 and 15. At any rate, if a composite error of a burst error and a random error occurs in a quasi-cyclic LDPC code corresponding to a mask matrix having the same structure as the parity check matrix (H3), a wrong correction result occurs due to the influence of the random error in the burst error correction phase, and the wrong correction result propagates via column processing. As a result, it may be impossible to properly correct a sufficient number of bits in the burst error section, and error correction may be difficult.

In this embodiment, the parity check matrix is created by the following method.

This method includes assigning one of “1” and “0” to each element of M rows×N columns, thereby creating a mask matrix having a column weight K, where M is an integer of 4 or more, N is an integer larger than M, and K is an integer of 2 or more.

This method further includes, for each element in the created mask matrix, arranging a cyclic permutation matrix having P rows×P columns at a corresponding position when the element is “1” and arranging a zero matrix having P rows×P columns at a corresponding position when the element is “0”, thereby creating a parity check matrix, where P is an integer of 2 or more.

Note that the mask matrix created by this method meets at least following conditions (a), (b), (c), (d), (e), (f), and (g).

(a) All of N column vectors in the mask matrix are different from each other.

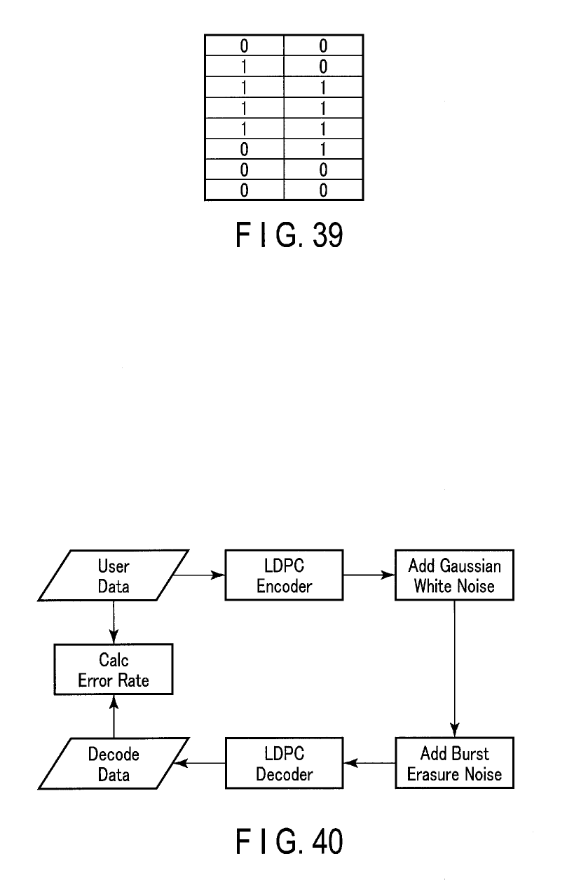

When the condition (a) is met, only (K−1) rows where the element “1” appears overlap at maximum between two arbitrary column vectors in the mask matrix, as shown in FIG. 39. That is, even when the first burst error and the second burst error occur in two arbitrary columns out of the mask matrix, the burst errors can be corrected. For this reason, the LDPC code corresponding to this mask matrix has an improved resistance to a plurality of burst errors as compared to the LDPC code corresponding to the mask matrix according to the first comparative example.

(b) A submatrix having M rows×L columns obtained by extracting L (L is an integer of (M−K+1) or less) arbitrary continuous columns from the mask matrix includes B₁ (B₁ is an integer of 1 or more) first correction rows.

The first correction rows indicate B₁ rows in which all uncorrected bits in the rows are corrected for the first time by correction processing of the first time, as described above. For this reason, the row weight of each of the B₁ first correction rows needs to be 1.

(c) The B₁ first correction rows have at least one “1” in total in each of A₁ (A₁ is an integer of 1 or more) first correction columns.

The first correction columns indicate A₁ columns corrected in the B₁ first correction rows by correction processing of the first time. In other words, all columns having “1” arranged in the B₁ first correction rows are handled as the first correction columns. Hence, the total number (A₁) of first correction columns is B₁ at maximum. If columns corrected by correction processing of the first time overlap between the B₁ first correction rows, A₁<B₁. On the other hand, if columns corrected by correction processing of the first time do not overlap at all between the B₁ first correction rows, A₁=B₁.

(d) The submatrix further includes Bᵢ (Bᵢ is an integer of 1 or more, i is any integer from 2 to I, and I is an integer of 2 or more) ith correction rows.

The ith correction rows indicate Bᵢ rows in which all uncorrected bits in the rows are corrected for the first time by correction processing of the ith time. In other words, the number of uncorrected bits needs to decrease from 2 or more to 1 in the Bᵢ ith correction rows by propagating the correction result of the (i−1)th time by propagation processing of the (i−1)th time. For this reason, the row weight of each of the Bᵢ ith correction rows is 2 or more. In addition, each of the Bᵢ first correction rows has at least one “1” in total in Aᵢ₋₁ (i−1)th correction columns. In this regard, the maximum number of (i−1)th propagation rows to which the correction result of the (i−1)th time is propagated by propagation processing of the (i−1)th time is Aᵢ₋₁×(K−1). Hence,

Bᵢ≦Aᵢ₋₁×(K−1) (7)

holds for Bᵢ.

(e) Each of the Bᵢ ith correction rows has “1” in one of Aᵢ (Aᵢ is an integer of 1 or more) ith correction columns included in a column set excluding the first correction column to the (i−1)th correction column, and the Bᵢ ith correction rows include at least one “1” in total in each of the ith correction columns.

The ith correction columns indicate Aᵢ columns corrected in the ith correction rows by correction processing of the ith time, as described above. In other words, all columns having “1” arranged in the Bᵢ ith correction rows out of the column set excluding the first correction column to the (i−1)th correction column are handled as the ith correction columns.

Hence, the total number (Aᵢ) of ith correction columns is Bᵢ at maximum. If columns corrected by correction processing of the ith time overlap between the Bᵢ ith correction rows, Aᵢ<Bᵢ. On the other hand, if columns corrected by correction processing of the ith time do not overlap at all between the Bᵢ ith correction rows, Aᵢ=Bᵢ. In this case, the Bᵢ ith correction rows have a total of one “1” in each of the Aᵢ ith correction columns. Hence, Aᵢ≦Bᵢ holds. From expression (7),

Aᵢ≦Aᵢ₋₁×(K−1) (8)

holds.

(f) The sum from A₁ to A_{I} equals L.

When the condition (f) is met, a burst error over L rows of the mask matrix can be corrected by I iterated decoding processes.

According to a mask matrix that meets the conditions (a), (b), (c), (d), (e), and (f), a burst error over L (L is an integer of 1 to (M−K+1) or less) columns that has occurred at an arbitrary position can be corrected, as will be described below.

To correct a burst error over L columns, at least one correction row is necessary for each column included in the L columns to correct errors in the column. According to the conditions (c) and (e), the first correction column is corrected in at least one first correction row. Similarly, the ith correction column is corrected in at least one ith correction row. For this reason, according to the mask matrix that meets the conditions (a), (b), (c), (d), (e), and (f), a burst error over L (L is an integer of 1 to (M−K+1) or less) columns, which occurs at an arbitrary position, can be corrected.

In addition, according to the mask matrix that meets the conditions (a), (b), (c), (d), (e), and (f), the upper limit of L is M−K+1, as will be described below.

As described concerning the conditions (c) and (e), B₁≧A₁ and Bᵢ≧Aᵢ. According to the condition (f), the sum from A₁ to A_{I} is L. Hence, the sum from B₁ to B_{I} is L or more. For this reason, the sum (M″) from B₁ to B_{I-1} is L−A_{I} or more.

In this case, when A_{I}=1, the submatrix includes not only the first to (I−1)th correction rows but also at least the Ith correction rows. When A_{I}=1, B_{I}=K. Hence, when A_{I}=1, M−M″≧A_{I}+K−1 holds.

On the other hand, when A_{I}≧2, the submatrix includes not only the first to (I−1)th correction rows but also at least the Ith correction rows. In addition, Ith propagation rows to which the error correction result of the Ith correction row propagates may exist. Each of the Ith propagation rows has two or more “1” in the A_{I} Ith correction columns. If each of (K−1) Ith propagation rows has “1” in all of A_{I} Ith correction columns, the sum of the total number of Ith correction rows and the total number of Ith propagation rows is minimized to A_{I}+K−1. Hence, even when A_{I}≧2, M−M″≧A_{I}+K−1 holds.

Hence, it can be confirmed that the upper limit value of L is M−K+1 by

M−(L−A_{I})≧M−M″≧A_{I}+K−1

M−(L−A_{I})≧A_{I}+K−1

M−L≧K−1

L≦M−K+1 (9)

(g) The total number of rows from the first correction row to the (I−1)th correction row equals the sum of the total number of columns from the first correction column to the (I−1)th correction column and S (S is an integer of 1 or more). Hence,

$${\sum }_{i = 1}^{I - 1} {B}_{i} = {\sum }_{i = 1}^{I - 1} {A}_{i} + S \qquad ( 10 )$$

holds.

As will be described later, when the condition (g) is met, the resistance to a composite error of a burst error and a random error can be increased. More specifically, in the burst error correction phase to correct a burst error over L columns of the mask matrix, it is possible to correct a wrong correction result generated by the influence of a random error by propagation processing of the jth time and also correct a wrong correction result generated in the past by correction processing and propagation processing in the future included in the burst error correction phase. Here, j is at least one integer of 1 to (I−1) or less which meets Bⱼ>Aⱼ.

Note that according to a mask matrix that meets the conditions (a), (b), (c), (d), (e), (f), and (g), the upper limit of L is M−K+1−S, as will be described below.

From the conditions (f) and (g),

M″=L−A_{I}+S (11)

holds.

From expressions (9) and (11),

M−M″≧A_{I}+K−1

M−(L−A_{I}+S)≧A_{I}+K−1

M−K+1−S≧L (12)

holds.

Note that to make the equal sign of expressions (12) hold, M−M″=A_{I}+K−1 needs to hold.

To allow M−M″=A_{I}+K−1 to hold when A_{I}=1, a total of K rows including the Ith correction rows need to remain in a row set formed by excluding the first to (I−1)th correction rows from the submatrix. As described above, when A_{I}=1, B_{I}=K. In addition, the Ith propagation rows do not exist. Hence, all of the total of K rows are made up of the Ith correction rows. That is, the submatrix cannot include any rows except the first correction rows, . . . , Ith correction rows. Note that to make B₁=K hold, A_{I-1}≧2 needs to hold based on expression (7).

To allow M−M″=A_{I}+K−1 to hold when A_{I}≧2, a total of (A_{I}+K−1) rows including the Ith correction rows and the Ith propagation rows need to remain in a row set formed by excluding the first to (I−1)th correction rows from the submatrix. As described above, when A_{I}≧2, the sum of the total number of Ith correction rows and the total number of the Ith propagation rows is minimized to A_{I}+K−1. Hence, all of the total of (A_{I}+K−1) rows are made up of the Ith correction rows and the Ith propagation rows. To minimize the sum of the total number of Ith correction rows and the total number of the Ith propagation rows, B₁=A_{I} needs to hold, and the submatrix needs to include (K−1) Ith propagation rows having “1” in all the A_{I} Ith correction columns.

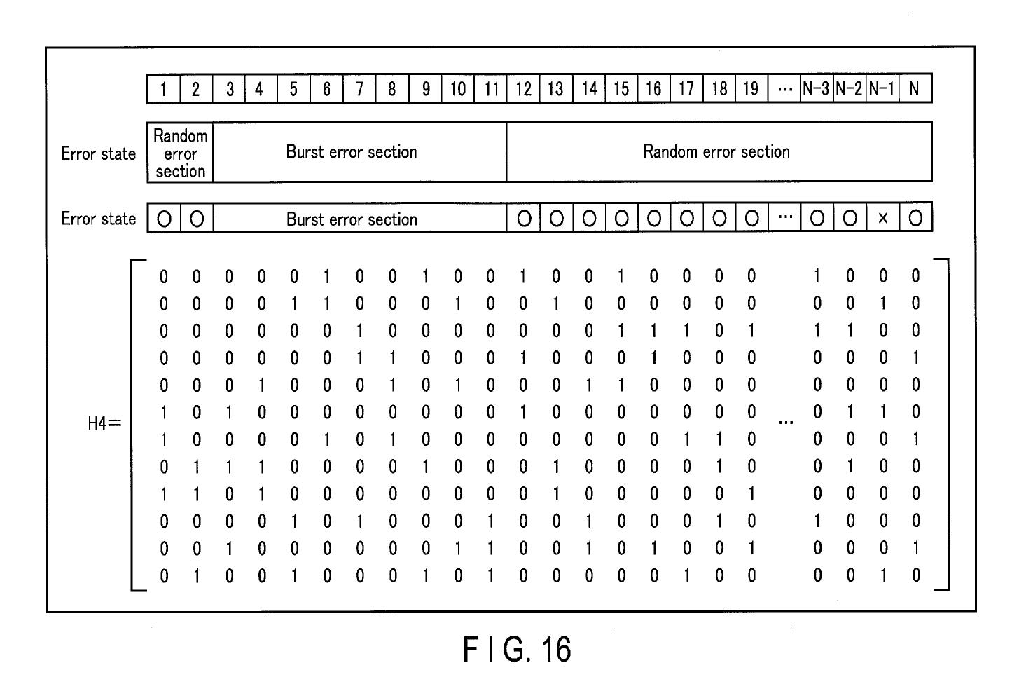

According to the mask matrix that meets the condition (g) in addition to the conditions (a), (b), (c), (d), (e), and (f), even when a composite error of a burst error and a random error occurs, degradation in the resistance to the burst error can be suppressed, as will be described below. Such a mask matrix (H4) is shown in, for example, FIG. 16.

Assume that in an LDPC code defined by the mask matrix (H4), a burst error occurs from the (2×P+1)th bit to the (11×P)th bit corresponding to the third to 11th columns of the mask matrix (H4), and a random error occurs in the ((N−2)×P+1) bit to the ((N−1)×P)th bit corresponding to the (N−1)th column of the mask matrix (H4).

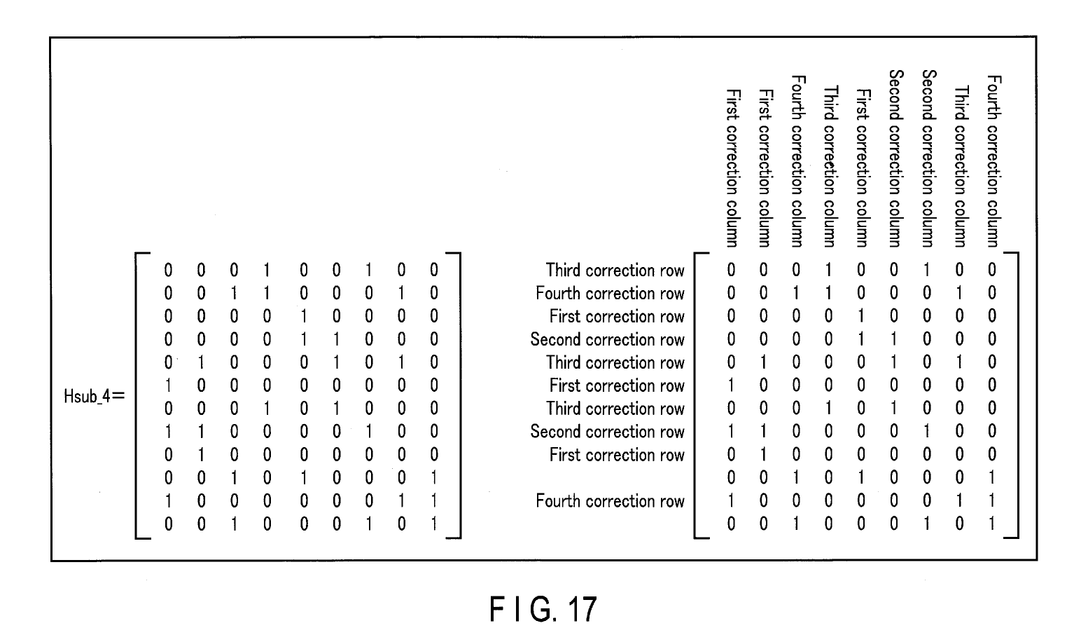

As shown in FIG. 17, a submatrix (Hsub_4) formed from column vectors from the third column up to the 11th column of the mask matrix (H4) can be extracted from the mask matrix (H4). The submatrix (Hsub_4) meets the above-described condition (g) because the total number of rows (=8) from the first correction row to the third (=I−1) correction row equals the sum of S (=1) and the total number of columns (=7) from the first correction column to the third (=I−1) correction column. More specifically, the number of third correction rows is larger than the number of third correction columns by one. It is therefore possible to correct a wrong correction result generated by the influence of a random error by propagation processing of the third time and also correct a wrong correction result generated in the past by correction processing and propagation processing in the future included in the burst error correction phase.

In the following description, elements of columns that are not the subjects of correction processing in the rows of the matrix (Hsub_4) will be expressed as “—”, and elements of columns that are the subjects of correction processing will be expressed as “⊚”, “⋄”, “◯”, “♦”, “×”, “Δ”, “▴”, “∇”, or “▾”, as in the example of the matrix (Hsub_3). At the start of correction processing of the first time, the burst error that has occurred in the (3×P+1) bit to the (12×P) bit is not corrected. Hence, a matrix in which all “1”s in the matrix (Hsub_4) shown in FIG. 17 are replaced with “×”, and all “0”s are replaced with “—” is obtained.

In this example, the (N−1)th column of the mask matrix (H4) has “1” in the second, sixth, and 12th rows. Hence, in row processing of the second, sixth, and 12th rows, the bits to be corrected may be corrected wrongly.

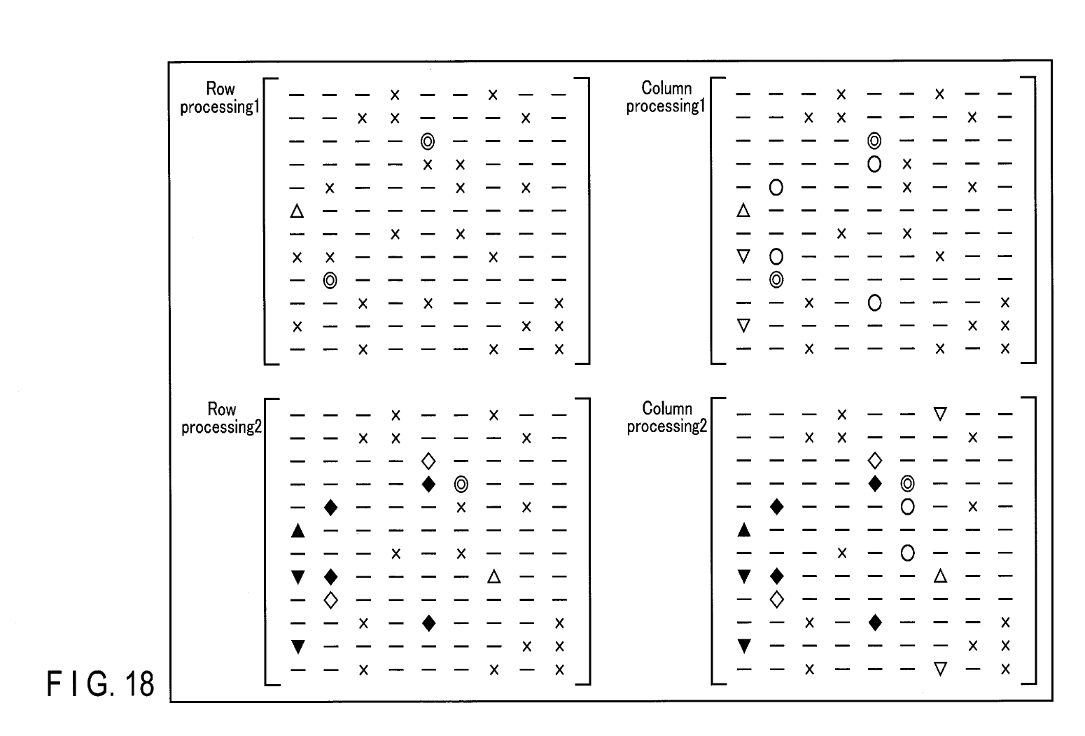

By correction processing of the first time, the third, sixth, and ninth rows that are the first correction rows are corrected. However, P bits corresponding to the third column of the sixth row are corrected wrongly due to the influence of random errors in the P bits corresponding to the (N−1)th column. Hence, a matrix labeled “row processing 1” in FIG. 18 is obtained as the result of the correction processing of the first time.

By the correction processing of the first time, P bits corresponding to the seventh column of the third row are properly corrected, P bits corresponding to the third column of the sixth row are corrected wrongly, and P bits corresponding to the fourth column of the ninth row are properly corrected. The correction result of the P bits corresponding to the seventh column of the third row propagates to the fourth and 10th rows in which the P bits are likewise the subjects of correction processing. The other correction results also propagate similarly. Note that the wrong correction result of the P bits corresponding to the third column of the sixth row propagates to the eighth and 11th rows in which the P bits are likewise the subjects of correction processing. Hence, a matrix labeled “column processing 1” in FIG. 18 is obtained as the result of propagation processing of the first time.

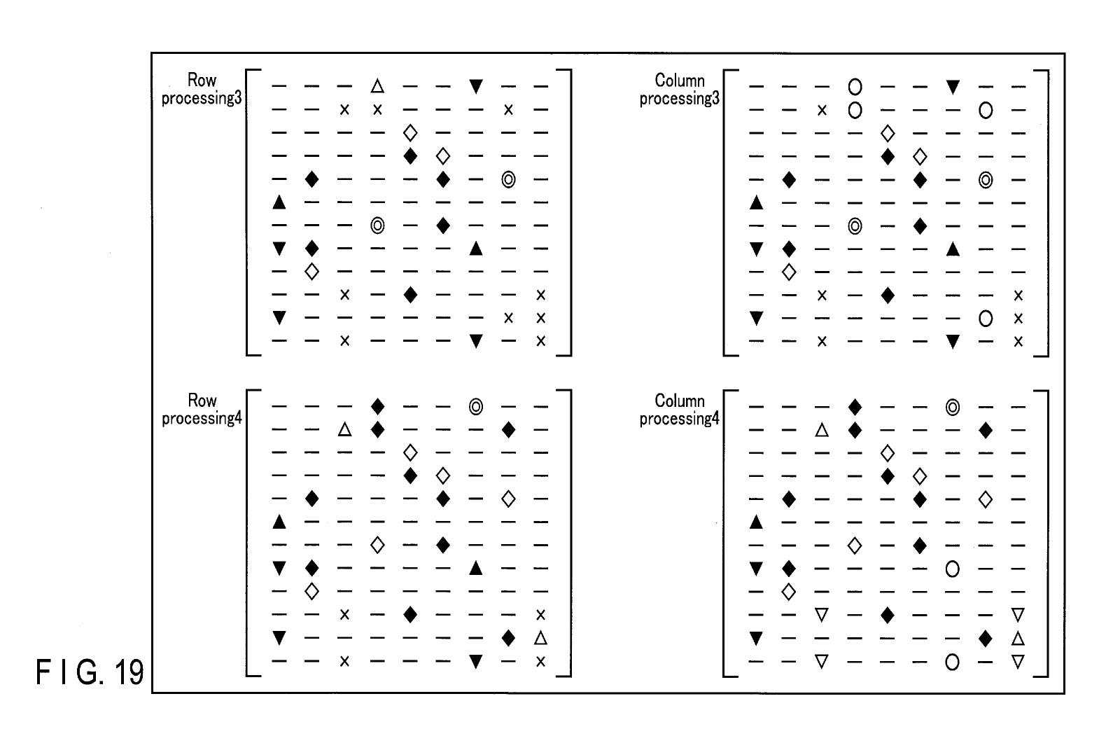

Subsequent correction processing and propagation processing progress is as shown in FIGS. 18 and 19. By correction processing of the third time, the first, fifth, and seventh rows that are the third correction rows are corrected. However, P bits corresponding to the sixth column of the first row may be corrected wrongly due to the influence of propagation of a wrong correction result to P bits corresponding to the ninth column of the first row by propagation processing of the second time. Hence, a matrix labeled “row processing 3” in FIG. 19 is obtained as the result of the correction processing of the third time.

By the correction processing of the third time, P bits corresponding to the sixth column of the first row are corrected wrongly, P bits corresponding to the 10th column of the fifth row are properly corrected, and P bits corresponding to the sixth column of the seventh row are properly corrected.

Focusing on the sixth column, correction results of both the first and seventh rows are obtained. That is, by propagation processing of the third time, the wrong correction result of the P bits corresponding to the sixth column of the first row propagates to the second and seventh rows in which the P bits are likewise the subjects of correction processing. On the other hand, the proper correction result of the P bits corresponding to the sixth column of the seventh row also propagates to the first and second rows in which the P bits are likewise the subjects of correction processing.

In iterated decoding of the LDPC code, a correction result is expressed using a probability value. Hence, if a probability value that expresses the proper correction result of the P bits corresponding to the sixth column of the seventh row is larger than a probability value that expresses the wrong correction result of the P bits corresponding to the sixth column of the first row, the P bits corresponding to the sixth column are properly corrected. That is, the wrong correction result in the first row is corrected by the proper correction result in the seventh row. The proper correction result propagates to the second row. The proper correction result in the seventh row is maintained regardless of the wrong correction result in the first row. Hence, a matrix labeled “column processing 3” in FIG. 19 is obtained as the result of the propagation processing of the third time.

A wrong correction result generated in the past may be corrected due to proper correction of the P bits corresponding to the sixth column. More specifically, by correction processing of the fourth time, the wrong correction result (generated by propagation processing of the second time) of the P bits corresponding to the ninth column of the first row may likewise be corrected due to the influence of the proper correction result of the P bits corresponding to the sixth column of the first row. Hence, a matrix labeled “row processing 4” in FIG. 19 is obtained as the result of the correction processing of the fourth time.

By propagation processing of the fourth time, the proper correction result of the P bits corresponding to the ninth column of the first row propagates to the eighth and 12th rows. As a result, the wrong correction result (generated by correction processing of the second time) of the P bits corresponding to the ninth column of the eighth row and the wrong correction result (generated by propagation processing of the second time) of the P bits corresponding to the ninth column of the 12th row may be corrected. More specifically, if the probability value that expresses the proper correction result is larger than the probability value that expresses the wrong correction result, the wrong correction result is corrected, as described above. When the wrong correction results are corrected, a matrix labeled “column processing 4” in FIG. 19 is obtained as the result of the propagation processing of the fourth time. At the end of the propagation processing of the fourth time, correction of the burst error ends. In correction processing of the fifth and subsequent times, error correction functions for bits with random errors and bits corrected wrongly until the propagation processing of the fourth time.

As described above with reference to FIGS. 16, 17, 18, and 19, when the condition (g) is met in addition to the conditions (a), (b), (c), (d), (e), and (f), it is possible to implement a high resistance to a composite error of a burst error and a random error. Meeting the condition (g) means that the number of correction rows exceeds the number of correction columns in at least one of iterated decoding processes of the first, . . . , (I−1)th times. For example, if the number of third correction rows exceeds the number of third correction columns, a wrong correction result generated by correction processing of the third time may be corrected by propagation processing of the third time. A wrong correction result generated by iterated decoding before the second time may also be corrected by iterated decoding of the fourth and subsequent times included in the burst error correction phase.

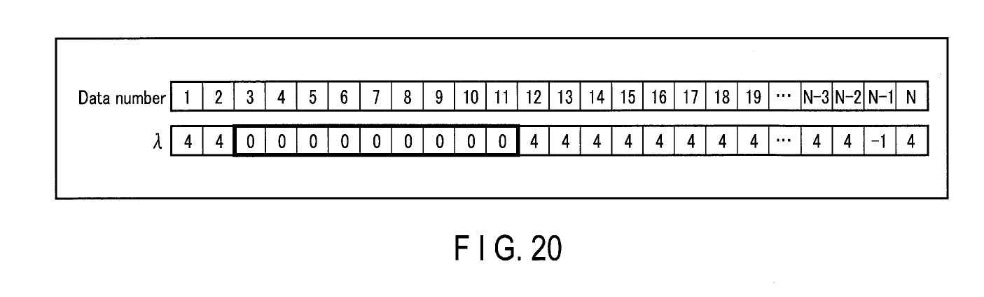

The effect of meeting the condition (g) can also be confirmed from a simulation (to be described later with reference to FIGS. 20, 21, 22, 23, and 24) of iterated decoding for an LDPC code defined by a parity check matrix having the same structure as the mask matrix (H4). In this simulation, a so-called Min-Sum decoding method is applied. The Min-Sum decoding will briefly be described below.

In the Min-Sum decoding method, all propagation results βₘₙ obtained by column processing (propagation processing) are initialized first (that is, set to zero). In addition, a channel value λ=(λ₁, λ₂, . . . , λ_{N}) is calculated based on a reception signal y=(y₁, y₂, . . . , y_{N}). The channel value λ is calculated using

$${λ}_{n} = {log}_{10} \frac{P ( {y}_{n} \vert {x}_{n} = 0 )}{P ( {y}_{n} \vert {x}_{n} = 1 )} \qquad ( 13 )$$

where n∈[1 to N] is represented, and x=(x₁, x₂, . . . , x_{N}) is a transmitted codeword bit.

Next, iterated decoding is performed. That is, a series of processes including row processing, column processing, determination of a temporarily estimated word, and parity check of the temporarily estimated word is performed. If parity check is OK, the temporarily estimated word is output. On the other hand, if parity check is NG, the number of iteration processes is incremented by one, and the series of processes is performed. If the number of iteration processes has already reached a preset maximum number, the temporarily estimated word (this is not a codeword because parity check is not satisfied) is output without performing the series of processes.

In row processing, a correction result αₘₙ is output using

$${α}_{mn} = ( {\prod }_{{n}^{′} ∈ A ( m ) \backslash n} sign ( {λ}_{n}^{′} + {β}_{mn}^{′} ) ) \cdot {min}_{{n}^{′} ∈ A ( m ) \backslash n} \vert {λ}_{n}^{′} + {β}_{mn}^{′} \vert \qquad ( 14 )$$

where A(m) is a set of the numbers of columns in which the elements “1” are arranged in the mth row of a parity check matrix. Hence, n′ represents an element of a set obtained by excluding n from the set A(m). In addition, sign(x) represents a function that returns 1 if the sign of x is positive, and −1 if the sign of x is negative.

In column processing, the propagation result βₘₙ is output using

$${β}_{mn} = {\sum }_{{m}^{′} ∈ B ( n ) \backslash m} {α}_{{m}^{′} n} \qquad ( 15 )$$

where B(n) is a set of the numbers of rows in which the elements “1” are arranged in the nth column of the parity check matrix. Hence, m′ represents an element of a set obtained by excluding m from the set B(n).

The temporarily estimated word is determined using

cₙ′=0 if sign(Dₙ)=1

cₙ′=1 if sign(Dₙ)=−1 (16)

Dₙ is calculated using

$${D}_{n} = {λ}_{n} + {\sum }_{{m}^{′} ∈ B ( n )} {α}_{{m}^{′} n} \qquad ( 17 )$$

Parity check is performed using

OK:(c₁′,c₂′, . . . , c_{N}′)H^{T}=0

NG:(c₁′,c₂′, . . . , c_{N}′)H^{T}≠0 (18)

where H represents the parity check matrix, and T indicates transposition of the matrix.

A simulation of iterated decoding for an LDPC code defined by a parity check matrix having the same structure as the mask matrix (H4) will be described below with reference to FIGS. 20, 21, 22, 23, and 24.

The codeword length of the LDPC code is N bits, which equals the number of columns of the parity check matrix. In this simulation, assume that a burst error occurs from the third bit up to the 11th bit, and a random error occurs in the (N−1)th bit. Also assume that all the transmitted codeword bits x₁, x₂, . . . , x_{N} are “0”. That is, if no error occurs, all the channel values λ₁, λ₂, . . . , λ_{N} are calculated as positive values.

Considering the above assumption, the channel value λ=(λ₁, λ₂, . . . , λ_{N}) shown in FIG. 20 is employed in this simulation. As shown in FIG. 20, since the signal values of the third to 11th bits are lost due to the burst error, the channel values λ₃, . . . , λ₁₁ are calculated as “0”. That is, according to equation (13), the channel values λ₃, . . . , λ₁₁ of the third to 11th bits indicate that the probability that the value is 0 and the probability that the value is 1 are equal. Additionally, as shown in FIG. 20, since the random error occurs in the (N−1)th bit, the corresponding channel value λ_{(N-1)} is calculated not as a positive value but as a negative value (for example, “−1”). That is, according to equation (13), the channel value λ_{N-1} of the (N−1)th bit indicates that the probability that the value is 1 is higher than the probability that the value is 0.

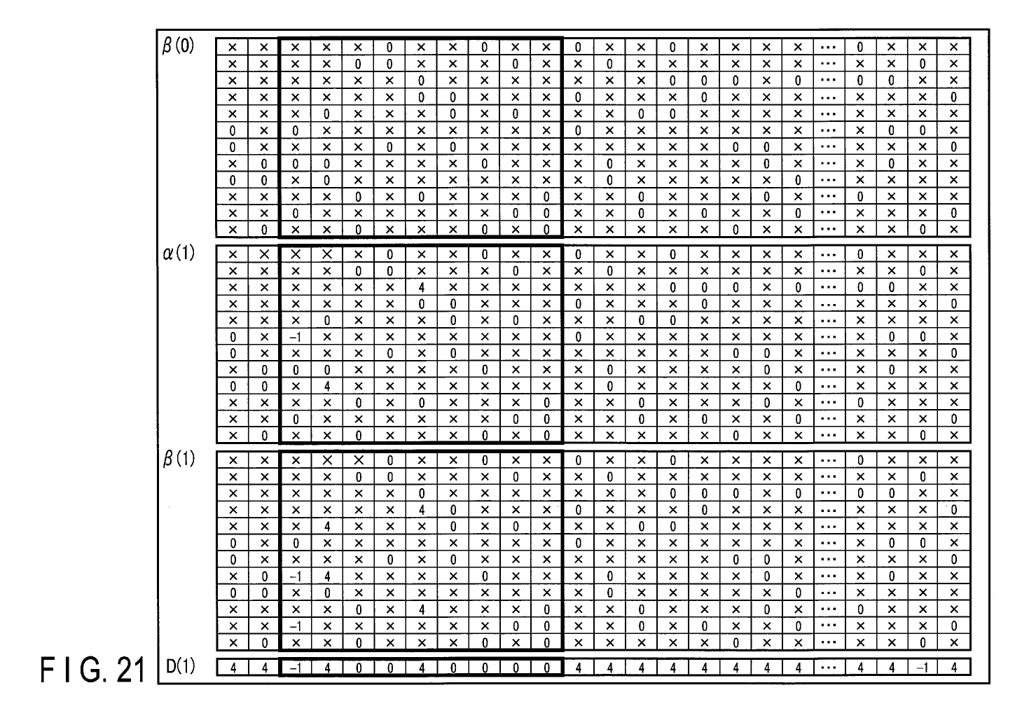

FIG. 21 shows the numerical calculation result of the initial value of the propagation result βₘₙ (see a table labeled “β(0)”), the correction result αₘₙ obtained by row processing of the first time (see a table labeled “α(1)”), the propagation result βₘₙ obtained by column processing of the first time (see a table labeled “β(1)”), and Dₙ calculated for temporarily estimated word determination of the first time (see a table labeled “D(1)”).

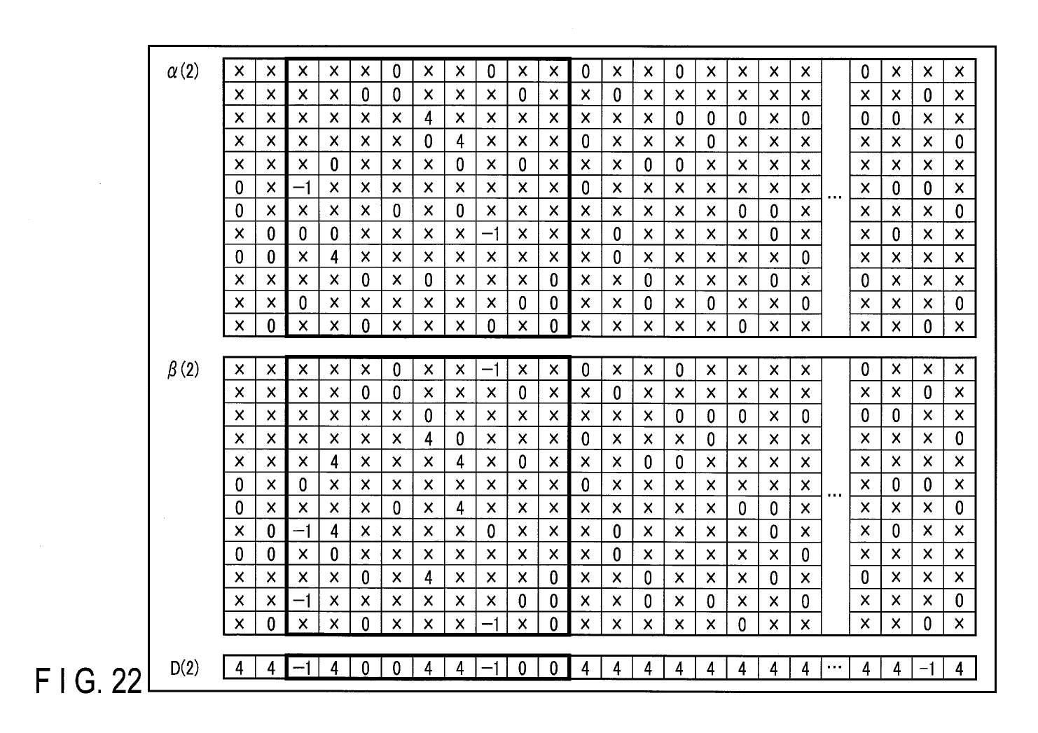

Focusing on the submatrix corresponding to the burst occurrence section, the third, sixth, and ninth rows that are the first correction rows are corrected by the row processing of the first time, as shown in the table labeled “α(1)” in FIG. 21. More specifically, the seventh column (α_{3,7}) of the third row and the fourth column (α_{9,4}) of the ninth row are properly corrected to a positive value “4”. On the other hand, the third column (α_{6,3}) of the sixth row is corrected wrongly to a negative value “−1” due to the influence of the random error of the (N−1)th bit. The correction results obtained by the row processing of the first time are propagated by the column processing of the first time. Iterated decoding processes of the second and subsequent times progress as shown in FIGS. 22, 23, and 24.

FIG. 22 shows the numerical calculation result of the correction result αₘₙ obtained by row processing of the second time (see a table labeled “α(2)”), the propagation result βₘₙ obtained by column processing of the second time (see a table labeled “β(2)”), and Dₙ calculated for temporarily estimated word determination of the second time (see a table labeled “D(2)”).

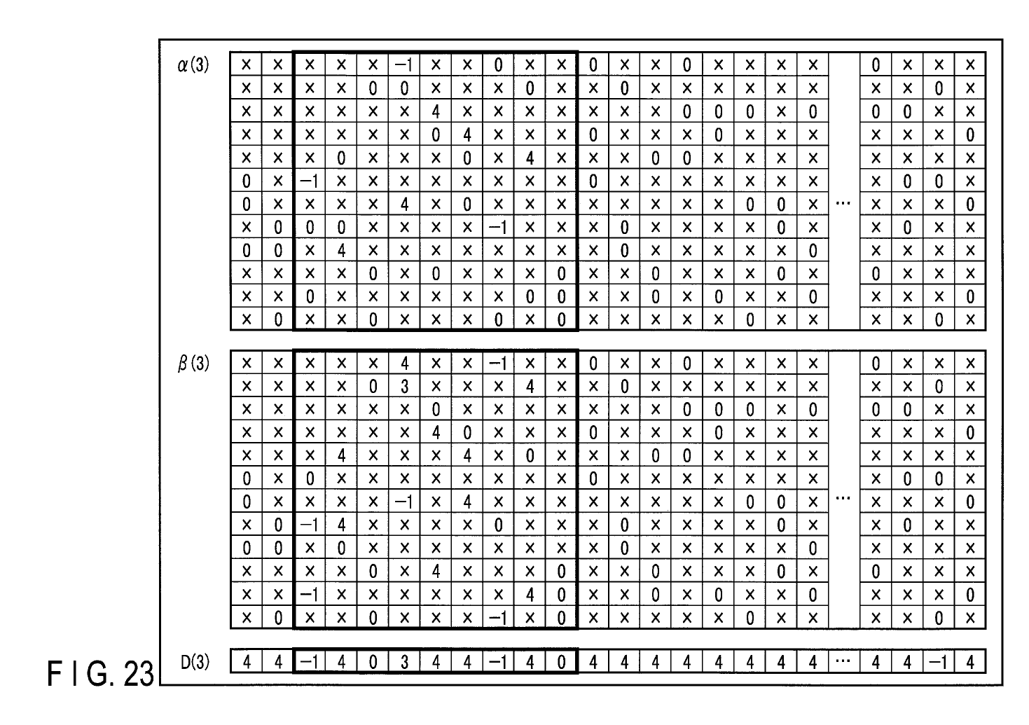

FIG. 23 shows the numerical calculation result of the correction result αₘₙ obtained by row processing of the third time (see a table labeled “α(3)”), the propagation result βₘₙ obtained by column processing of the third time (see a table labeled “β(3)”), and Dₙ calculated for temporarily estimated word determination of the third time (see a table labeled “D(3)”).

Focusing on the submatrix corresponding to the burst occurrence section, the first, fifth, and seventh rows that are the third correction rows are corrected by the row processing of the third time, as shown in the table labeled “α(3)” in FIG. 23. That is, the sixth column (α_{1,6}) of the first row is corrected wrongly to a negative value “−1” due to the influence of the random error of the (N−1)th column. On the other hand, the 10th column (α_{5,10}) of the fifth row and the sixth column (α_{7,6}) of the seventh row are properly corrected to a positive value “4”.

Focusing on the sixth column of the table labeled “α(3)” in FIG. 23, the correction results of both the first and seventh rows (that is, a plurality of rows) are obtained. As shown in the table labeled “β(3)” in FIG. 23, the correction results of the sixth column of the first and seventh rows are propagated in the sixth column by the column processing of the third time.

More specifically, as the propagation result β_{1,6} of the sixth column of the first row, the correction result α_{7,6} of the sixth column of the seventh row propagates. Since α_{7,6} is “4”, β_{1,6} is “4” (that is, positive value). As the propagation result β_{2,6} of the sixth column of the second row, the sum of the correction result α_{1,6} of the sixth column of the first row and the correction result α_{7,6} of the sixth column of the seventh row propagates. Since α_{1,6} is “−1”, and α_{7,6} is “4”, β_{2,6} is “3”. That is, although the sixth column of the first row is corrected wrongly, a proper propagation result is given to the sixth column of the second row. As the propagation result β_{7,6} of the sixth column of the seventh row, the correction result α_{1,6} of the sixth column of the first row propagates. Since α_{1,6} is “−1”, β_{7,6} is “−1”.

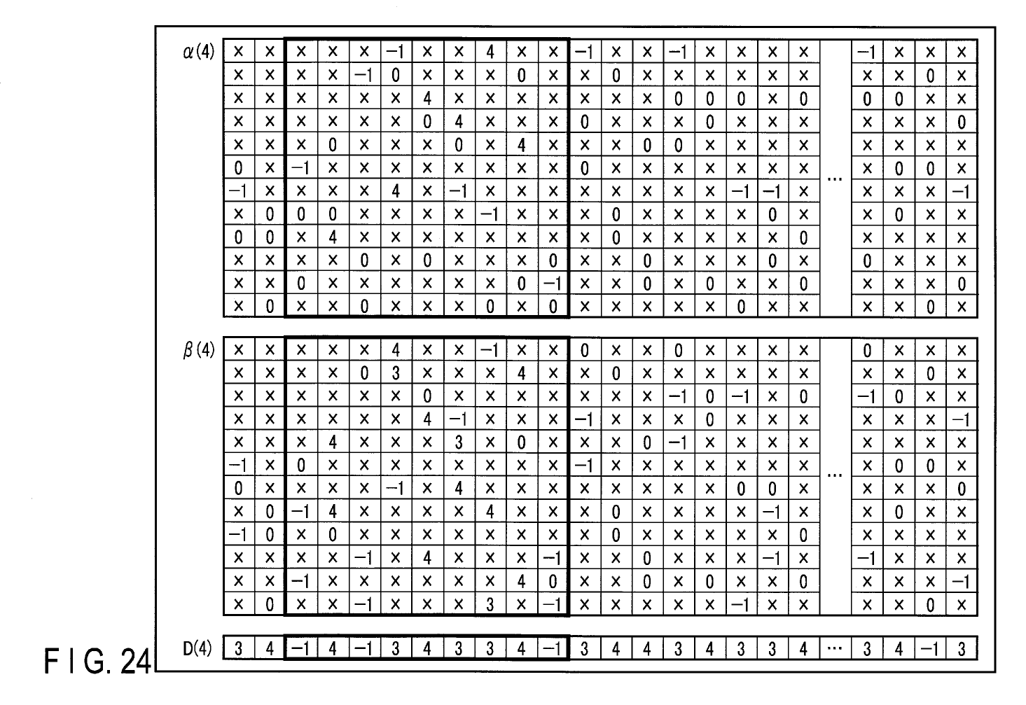

FIG. 24 shows the numerical calculation result of the correction result αₘₙ obtained by row processing of the fourth time (see a table labeled “α(4)”), the propagation result βₘₙ obtained by column processing of the fourth time (see a table labeled “β(4)”), and Dₙ calculated for temporarily estimated word determination of the fourth time (see a table labeled “D(4)”).

Focusing on the submatrix corresponding to the burst occurrence section, the fifth column of the second row and the 11th column of the 11th row that are the fourth correction rows are corrected wrongly by the row processing of the fourth time, as shown in the table labeled “α(4)” in FIG. 24. In addition, since the proper propagation result β_{1,6} is given to the sixth column of the first row by the propagation processing of the third time, the ninth column of the first row is properly corrected as well (α_{1,9}). As shown in the table labeled “β(4)” in FIG. 24, the correction result of the ninth column of the first row is propagated in the ninth column by the column processing of the fourth time. As a result, the ninth bit is properly corrected.

As shown in the table labeled “D(4)” in FIG. 24, at the end of iterated decoding of the fourth time, D₃, . . . , D₁₁ are corrected to nonzero values for all bits in the burst error occurrence section. Hence, in iterated decoding of the fifth and subsequent times, error correction functions for bits with random errors and bits corrected wrongly in the burst error correction phase. That is, iterated decoding is executed until the number of iterated decoding processes reaches the maximum value, or parity check of the temporarily estimated word results in OK.

In the parity check matrix creation method according to this embodiment, the design of the mask matrix affects the error resilience of the LDPC code. For example, the larger S is, the smaller the total number of correction columns is, as compared to the total number of correction rows. That is, as S becomes large, the effect of correcting a wrong correction result caused by a random error by propagation processing improves, or the number of correction columns on which the effect can be obtained increases. On the other hand, as S becomes large, L becomes small, as indicated by expressions (12), and correction capability to a burst error therefore degrades. Hence, the value S and the arrangement of correction columns and correction rows are preferably designed in consideration of desired correction capability.

As described above, j<I. If j=I, a wrong correction result generated by correction processing of the Ith time may be corrected by propagation processing of the Ith time. However, since the burst error correction phase is ended by iterated decoding of the Ith time, it is impossible to correct a wrong correction result generated in the past by correction processing and propagation processing in the future included in the burst error correction phase. Hence, j<I preferably holds. That is, if A_{I}≧2, A_{I}=B_{I} is preferably designed. Note that if A_{I}=1, B_{I}=K, as described above.

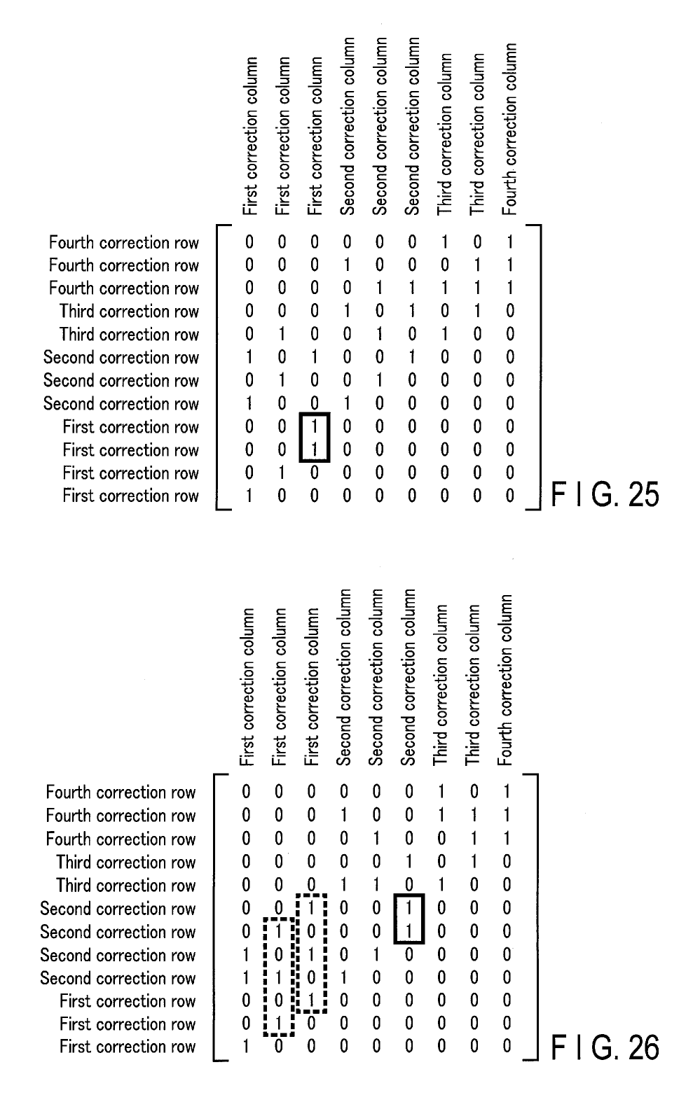

FIG. 25 shows a submatrix in a case where S=1, and j=1. In the submatrix shown in FIG. 25, the third column of the ninth row and the third column of the 10th row are “1”. Hence, even if a wrong correction result is obtained in one of the ninth and 10th rows by correction processing of the first time, the wrong correction result may be corrected by propagation processing of the first time. That is, even if one of the ninth and 10th rows of a column corresponding to a bit where a random error has occurred is “1”, a bit corresponding to the third column of the submatrix may be corrected properly.

FIG. 26 shows a submatrix in a case where S=1, and j=2. In the submatrix shown in FIG. 26, the sixth column of the sixth row and the sixth column of the seventh row are “1”. Hence, even if a wrong correction result is obtained in one of the sixth and seventh rows by correction processing of the second time, the wrong correction result may be corrected by propagation processing of the second time. That is, even if one of the sixth and seventh rows of a column corresponding to a bit where a random error has occurred is “1”, a bit corresponding to the sixth column of the submatrix may be corrected properly.

In addition, since a proper correction result is obtained in the sixth column of the sixth row and the sixth column of the seventh row, the correction results of the third column of the sixth row and the second column of the seventh row may be corrected by correction processing of the third time. That is, even if wrong correction results are obtained in the second and third columns by the correction processing and propagation processing of the first time, the wrong correction results may be corrected by the correction processing and propagation processing of the third time. Hence, when j=2, the effect of correcting a wrong correction result can be expected in a wider range, as compared to a case where j=1.

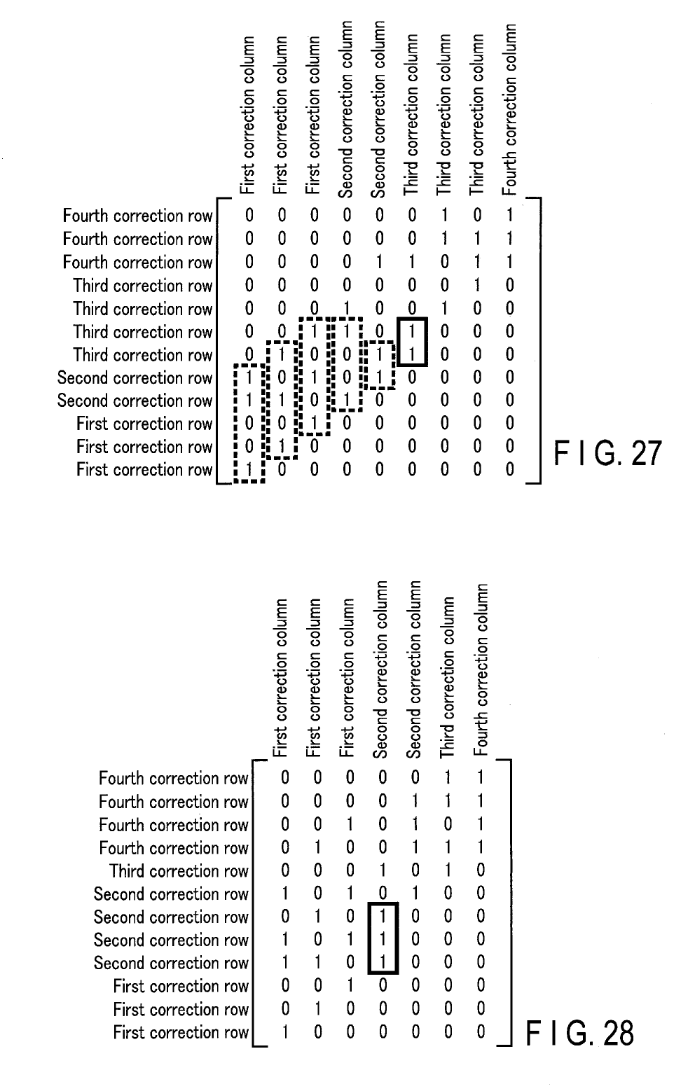

FIG. 27 shows a submatrix in a case where S=1, and j=3. In the submatrix shown in FIG. 27, the sixth column of the sixth row and the sixth column of the seventh row are “1”. Hence, even if a wrong correction result is obtained in one of the sixth and seventh rows by correction processing of the third time, the wrong correction result may be corrected by propagation processing of the third time. That is, even if one of the sixth and seventh rows of a column corresponding to a bit where a random error has occurred is “1”, a bit corresponding to the sixth column of the submatrix may be corrected properly.

In addition, since a proper correction result is obtained in the sixth column of the sixth row and the sixth column of the seventh row, the correction results of the third column of the sixth row, the fourth column of the sixth row, the second column of the seventh row, and the fifth column of the seventh row may be corrected by correction processing of the fourth time. That is, even if wrong correction results are obtained in the second, third, fourth, and fifth columns by the correction processing and propagation processing of the first and second times, the wrong correction results may be corrected by the correction processing and propagation processing of the fourth time. Hence, when j=3, the effect of correcting a wrong correction result can be expected in a wider range, as compared to a case where j=1 or j=2.

Note that a wrong correction result generated in the early stage of iterated decoding widely propagates as the iterated decoding progresses. Hence, if j is too large, it may be impossible to sufficiently correct the wrong correction result generated in the early stage of iterated decoding. However, the correcting effect can be expected for a wrong correction result generated in iterated decoding several times before the jth time. Hence, 2≦j≦I−1 is preferably set as compared to j=1.

FIG. 28 shows a submatrix in a case where S=2. In the submatrix shown in FIG. 28, the fourth column that is the second correction column has “1” in the seventh, eighth, and ninth rows that are the second correction rows. Hence, even if a wrong correction result is obtained in one or two of the seventh, eighth, and ninth rows by correction processing of the second time, the wrong correction result may be corrected by propagation processing of the third time. That is, even if one or two of the seventh, eighth, and ninth rows of a column corresponding to a bit where a random error has occurred are “1”, a bit corresponding to the fourth column of the submatrix may be corrected properly. Hence, the capability of correcting a bit corresponding to a specific ith correction column can be expected to be improved by setting the number of jth correction rows to which “1” included in a specific jth correction column belongs to a large number.

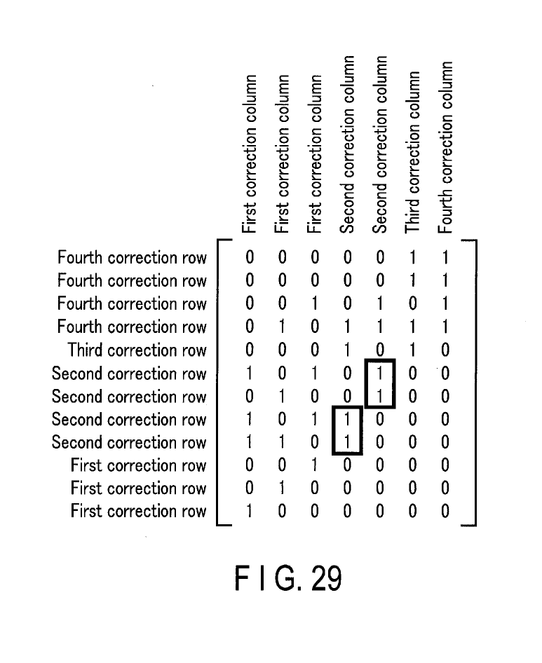

FIG. 29 shows a submatrix in a case where S=2. In the submatrix shown in FIG. 29, the fourth column that is the second correction column has “1” in the eighth and ninth rows that are the second correction rows. Hence, even if a wrong correction result is obtained in one of the eighth and ninth rows by correction processing of the second time, the wrong correction result may be corrected by propagation processing of the second time. That is, even if one of the eighth and ninth rows of a column corresponding to a bit where a random error has occurred is “1”, a bit corresponding to the fourth column of the submatrix may be corrected properly.

Additionally, in the submatrix shown in FIG. 29, the fifth column that is the second correction column has “1” in the sixth and seventh rows that are the second correction rows. Hence, even if a wrong correction result is obtained in one of the sixth and seventh rows by correction processing of the second time, the wrong correction result may be corrected by propagation processing of the second time. That is, even if one of the sixth and seventh rows of a column corresponding to a bit where a random error has occurred is “1”, a bit corresponding to the fifth column of the submatrix may be corrected properly. Hence, the range where the effect of correcting a wrong correction result can be expected can be widened by setting the number of jth correction columns including “1” belonging to a plurality of jth correction rows to a large number. That is, the correctable error pattern can be diversified as compared to FIG. 28.

To maximize the number of jth correction columns including “1” belonging to a plurality of jth correction rows in a case where S is constant, the number of “1”s belonging to the jth correction row included in each of the jth correction columns needs to be 2 at maximum.

Note that the maximum value of S is M−A_{I}−K+2−I. The maximum value of S cab be derived, based on the conditions (c) and (e) and expressions (10) and (12), by

$${\sum }_{i = 1}^{I - 1} {B}_{i} = {\sum }_{i = 1}^{I - 1} {A}_{i} + S \\ M - ( {A}_{I} + K - 1 ) \geq {\sum }_{i = 1}^{I - 1} {B}_{i} = {\sum }_{i = 1}^{I - 1} {A}_{i} + S \geq ( I - 1 ) + S \\ M - {A}_{I} - K + 1 \geq I - 1 + S \\ M - {A}_{I} - K + 2 - I \geq S \qquad ( 19 )$$

If the number of “1”s belonging to the jth correction row included in each of the jth correction columns is 2 at maximum, S is maximized when all jth correction columns include “1” belonging to two jth correction rows (that is, equation (20) below holds).

$${\sum }_{i = 1}^{I - 1} Bi = 2 \times {\sum }_{i = 1}^{I - 1} Ai \qquad ( 20 )$$

The maximum value of S can be derived, from equations (10) and (20), as

$$S = \frac{1}{2} \times {\sum }_{i = 1}^{I - 1} {B}_{i} \qquad ( 21 )$$

However, since S is an integer, fractions after the decimal point on the right-hand side of equation (21) need to be dropped.

A parity check matrix creation method according to this embodiment will be described below in detail. In this embodiment, a submatrix having M rows×L columns called an initial matrix (Mᵢₙᵢ) is created, and the number of columns of the initial matrix is extended from L to N, thereby creating a mask matrix.

Here, M is the row size of the mask matrix, L≦S M−K+1−S, L is a burst error length correctable by an LDPC code corresponding to the mask matrix, K is the column weight of the mask matrix, I is the maximum number of iterated decoding processes necessary to correct a burst error over L columns, and S is the difference between the total number of rows from the first correction row to the (I−1)th correction row and the total number of columns from the first correction column to the (I−1)th correction column.

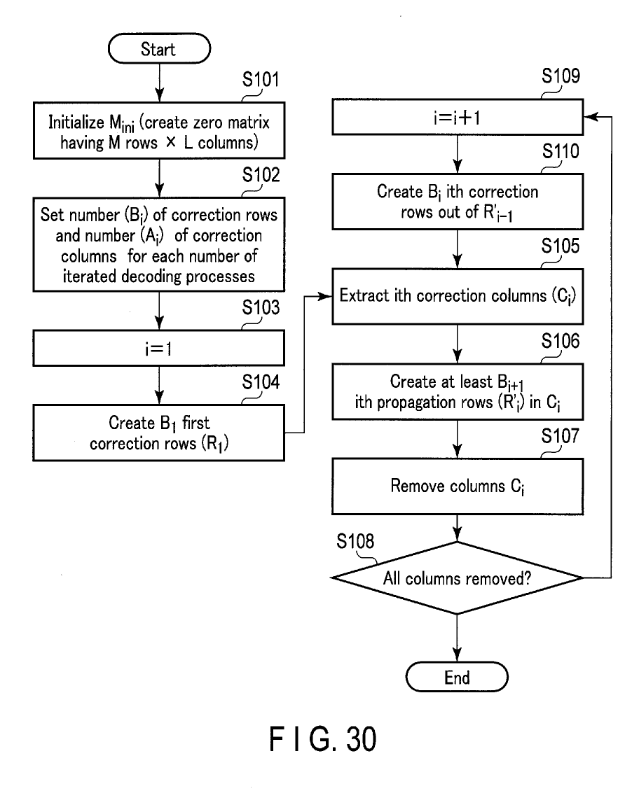

FIG. 30 shows the creation processing of the initial matrix (Mᵢₙᵢ). The processing shown in FIG. 30 can be executed by a processor connected to a memory. Typically, a computer executes the processing shown in FIG. 30. The processing shown in FIG. 30 starts from step S101.

In step S101, the initial matrix (Mᵢₙᵢ) is initialized. More specifically, a zero matrix having M rows×L columns is created in the work area of the memory. In addition, the total number (Aᵢ) of ith correction columns (Cᵢ) and the total number (Bᵢ) of ith correction rows (Rᵢ) are set (step S102). The ith correction column (Cᵢ) indicates a column to be corrected in the ith correction row (Rᵢ) by correction processing of the ith time, where i is a variable that specifies the number of iterated decoding processes, and 1≦i≦I. In addition, Aᵢ≧1. I is a value representing the maximum number of iterated decoding processes necessary to correct a burst error over L columns, as described above, and is preferably set to L/2 or less. In addition,

$${\sum }_{i = 1}^{I - 1} {A}_{i} = L \qquad ( 22 )$$

holds concerning Aᵢ and I.

In step S103, i=1 is set, and the process advances to step S104. In step S104, B₁ first correction rows (R₁) are created. Note that B₁≧A₁. Here, the first correction row indicates a row including one uncorrected bit out of the subjects of correction processing of the first time. For this reason, the row weight is 1 in all the first correction rows. B₁ first correction rows have at least one “1” in total in each of A₁ different columns (that is, first correction columns). After step S104, the process advances to step S105.

In step S105, the ith correction columns (Cᵢ) are extracted. As is set in step S102, Aᵢ ith correction columns (Cᵢ) exist. Focusing on the ith correction columns (Cᵢ) extracted in step 105, Bᵢ₊₁ (≧Aᵢ₊₁) or more ith propagation rows (R′ᵢ) are created (step S106). The ith propagation row (R′ᵢ) indicates a row to which at least one correction result in total is propagated by propagation processing of the ith time. That is, the ith propagation row (R′ᵢ) has at least one “1” in total in the Aᵢ ith correction columns. However, rows already created as the first, . . . , ith correction rows (R₁, . . . , Rᵢ) are excluded from the candidates of the ith propagation rows. The column weight of each ith correction column (Cᵢ) is adjusted to K by “1” assigned to the ith propagation rows.

When the ith propagation rows (R′ᵢ) are created in step S106, the ith correction columns (Cᵢ) are decided. Hence, the ith correction columns (Cᵢ) are deleted from the work area of the memory (step S107). When all columns are deleted from the work area of the memory in step S107, creation of the initial matrix (Mᵢₙᵢ) is completed, and the processing thus ends. Otherwise, the process jumps to step S109.

In step S109, i is incremented by one, and the process advances to step S110. In step S110, Bᵢ ith correction rows (Rᵢ) are created out of the (i−1)th propagation rows (R′ᵢ₋₁) created in step S106 of the previous time. Note that Bᵢ≧Aᵢ. Here, the Bᵢ ith correction rows have at least one “1” in total in each of the Aᵢ different columns (that is, ith correction columns) included in a column set formed by excluding the A₁ first correction columns to the Aᵢ₋₁ (i−1)th correction columns. In addition, each of the Bᵢ ith correction rows has only one “1” in the Aᵢ ith correction columns. After step S110, the process advances to step S105.

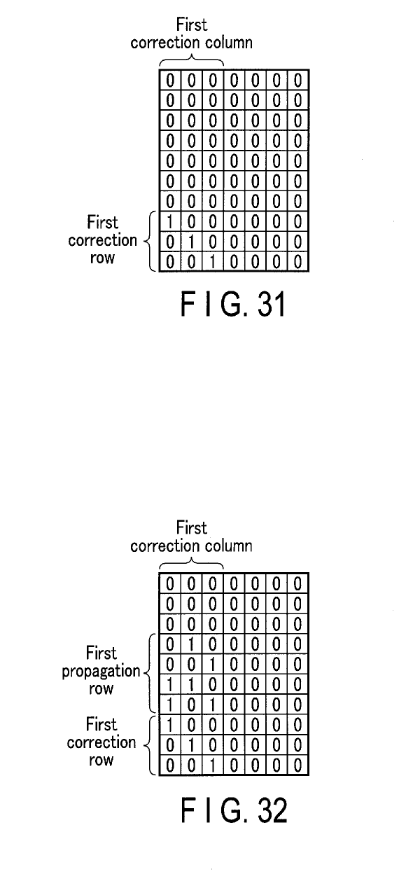

A state in which the initial matrix (Mᵢₙᵢ) of a mask matrix is generated through the processing shown in FIG. 30 will be described below with reference to FIGS. 31, 32, 33, 34, 35, 36, and 37. Note that in this description, M=10, K=3, S=1, and L=7 (=M−K+1−S).

First, a zero matrix having 10 rows×7 columns is created in the work area of the memory (step S101). In addition, A₁=3, A₂=2, A₃=2, B₁=3, B₂=3, and B₃=2 are set (step S102). That is, in this example, I=3, and B₂>A₂.

As shown in FIG. 31, 3 (=B₁) first correction rows (R₁) are created (step S104), and the first correction columns (C₁) are extracted (step S105). More specifically, the eighth, ninth, and 10th rows are created as the first correction rows such that the row weight becomes 1, and the columns where the element “1” appears do not overlap each other. In the example shown in FIG. 31, the element “1” is given to the first column of the eighth row, the second column of the ninth row, and the third column of the 10th row. That is, the first, second, and third columns are extracted as the first correction columns (C₁).

Next, as shown in FIG. 32, 4 (≧3=B₂) first propagation rows (R′₁) are created, excluding the first correction columns (step S106). More specifically, the element “1” is assigned to the first propagation rows (that is, fourth, fifth, sixth, and seventh rows) such that the column weight of the first correction columns becomes 3. At this time, the first correction columns (C₁) are decided and deleted from the work area of the memory (step S107). However, the processing continues because undecided columns remain.

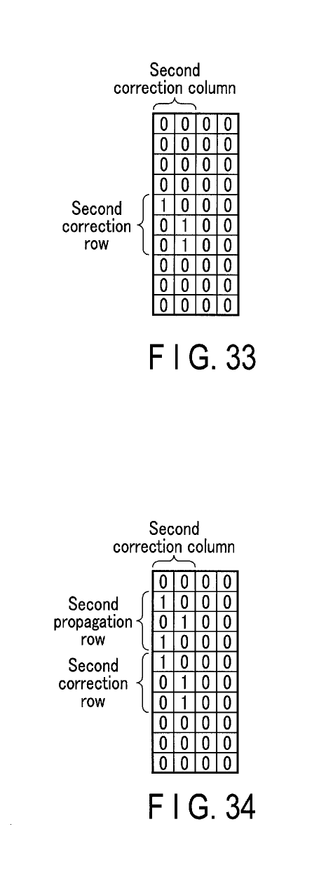

As shown in FIG. 33, 3 (=B₂) second correction rows (R₂) are created out of the first propagation rows (step S110), and the second correction columns (C₂) are extracted (step S105). Then, as shown in FIG. 34, 3 (≧2=B₃) second propagation rows (R′₂) are created, excluding the first correction columns and the second correction columns (step S106). At this time, the second correction columns (C₂) are decided and deleted from the work area of the memory (step S107). However, the processing continues because undecided columns remain.

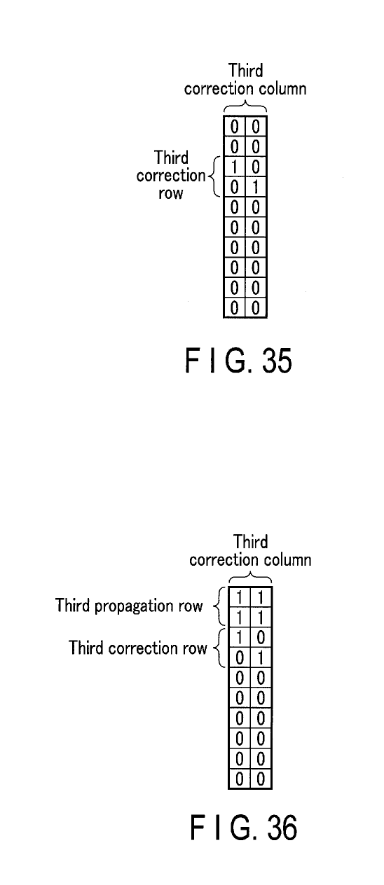

As shown in FIG. 35, 2 (=B₃) third correction rows (R₃) are created out of the second propagation rows (step S110), and the third correction columns (C₃) are extracted (step S105). Then, as shown in FIG. 36, 2 (0≧B₄) third propagation rows (R′₃) are created, excluding the first correction columns, the second correction columns, and the third correction columns (step S106). At this time, the third correction columns (C₃) are decided and deleted from the work area of the memory (step S107). In addition, the processing ends because no undecided column remains.

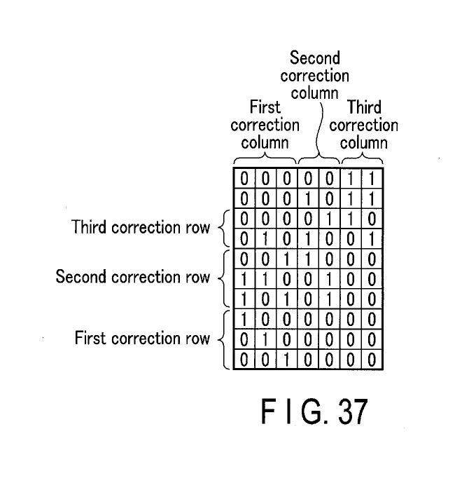

According to this example, the initial matrix (Mᵢₙᵢ) shown in FIG. 37 is created. According to the initial matrix shown in FIG. 37, a burst error over seven columns can be corrected by 3 (=I) iterated decoding processes.

On the other hand, according to the mask matrix (Z1 or Z2) of the first comparative example, 4 (=L/2=7/2=3.5→4) iterated decoding processes are necessary to correct the burst error over seven columns, as described above.

Hence, according to this initial matrix, it is possible to reduce the number of iterated decoding processes necessary to correct the burst error over seven columns as compared to the mask matrix (Z1 or Z2) of the first comparative example. Note that in this example, A₁=3, A₂=2, and A₃=2 are set, thereby achieving I=3. However, an arbitrary positive integer can be set to Aᵢ as long as expressions (8) and (22) are met.

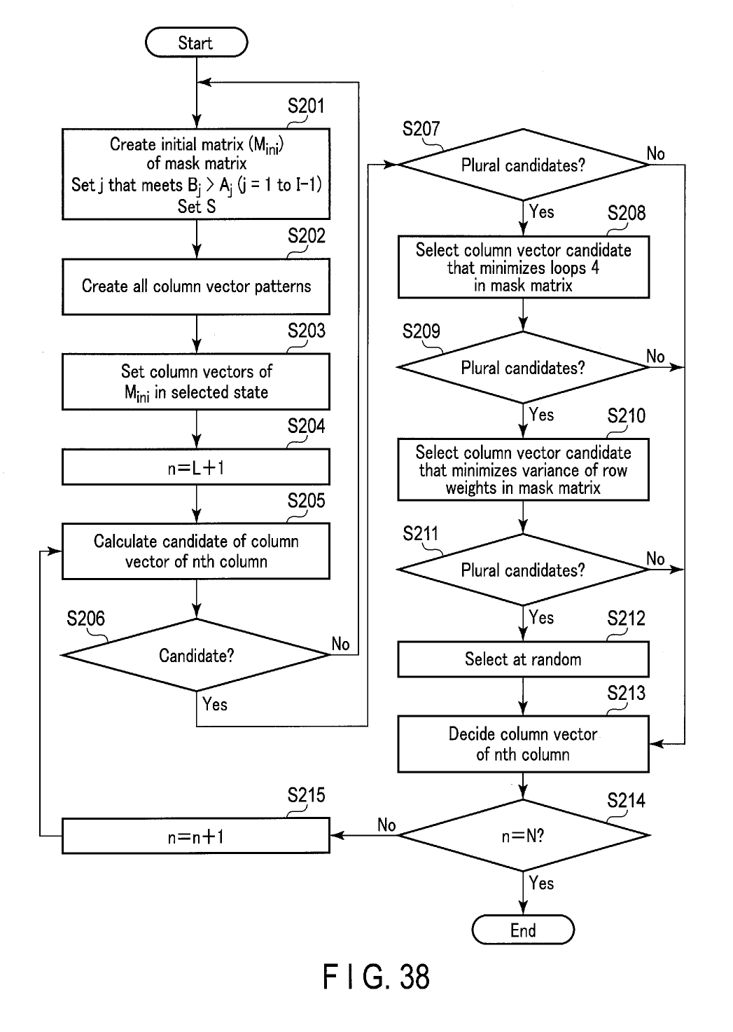

As described above, the mask matrix is created by, for example, extending the number of columns of the initial matrix (Mᵢₙᵢ) created in accordance with the flowchart of FIG. 30 from L to N. FIG. 38 shows creation processing of a mask matrix. The processing shown in FIG. 38 is executed by a processor connected to a memory. Typically, a computer executes the processing shown in FIG. 38. The processing shown in FIG. 38 starts from step S201.

In step S201, the initial matrix (Mᵢₙᵢ) of a mask matrix is created. That is, for example, processing shown in FIG. 30 is executed in step S201. Additionally, in step S201, at least one j (1≦j≦I−1) that satisfies Bj>Aj is set, and S is set as well. Next, all column vector patterns are created (step S202). More specifically, all patterns of column vectors having K elements “1” and (M−K) elements “0” are created. The total number of such column vector patterns is _{M}C_{K}. When, for example, M=10 and K=3, 120 patterns can be created.

Out of the column vectors created in step S202, those included in the initial matrix (Mᵢₙᵢ) created in step S201 are handled as selected. If, for example, L=7, seven column vectors included in the initial matrix are handled as selected. The selected column vectors cannot be included in candidates from step S205 to be described later.

By this handling, only (K−1) rows where the element “1” appears overlap at maximum between two arbitrary column vectors in the mask matrix, as shown in FIG. 39. That is, even when errors occur in two arbitrary columns out of the mask matrix, they can be corrected. For this reason, the LDPC code corresponding to the mask matrix created by the processing shown in FIG. 38 has an improved resistance to a plurality of burst errors as compared to the LDPC code corresponding to the mask matrix according to the first comparative example.

In step S204, n=L+1 is set, where n is a variable that specifies a column to be processed. When steps S203 and S204 are completed, the process advances to step S205.

In step S205, a candidate selectable as the nth column vector is selected. If the following three conditions are met in a case where a certain column vector pattern is employed as the nth column vector, the column vector pattern is selected as one of candidates. As the first condition, a burst error that has occurred from the (n−L+1)th column to the nth column can be corrected within the maximum number of iterated decoding processes (=I). As the second condition, for all of one or more values j set in step S201, Bⱼ>Aⱼ holds in a submatrix formed from the (n−L+1)th column to the nth column of the mask matrix. As the third condition, equation (10) described above holds in the submatrix formed from the (n−L+1)th column to the nth column of the mask matrix. After step S205, the process advances to step S206.

If one or more candidates are selected in step S206, the process advances to step S207. Otherwise, since no mask matrix can be created, the process returns to step S201 to newly create the initial matrix (Mᵢₙᵢ). If a plurality of candidates are selected in step S207, the process advances to step S208. If the candidates are narrowed down to one, the process advances to step S213.

In step S208, a candidate that minimizes the number of generated loops 4 in the mask matrix when a column vector is employed as the nth column vector of the mask matrix is further selected. If a plurality of candidates are still selected in step S208, the process advances to step S210. If the candidates are narrowed down to one, the process advances to step S213 (step S209).

In step S210, a candidate that minimizes the variance of the row weight in the mask matrix when a column vector is employed as the nth column vector of the mask matrix is further selected. If a plurality of candidates are still selected in step S210, the process advances to step S212. if the candidates are narrowed down to one, the process advances to step S213 (step S211).

In step S212, an arbitrary candidate is selected, for example, at random from the plurality of candidates, and the process advances to step S213. Note that step S212 can be implemented by an arbitrary technique for selecting one of a plurality of candidates.

In step S213, since the candidates are narrowed down to one, the candidate is decided as the column vector of the nth column of the mask matrix. If n=N at the end of step S213, the mask matrix creation is completed, and the processing therefore ends. Otherwise, the process advances to step S215 (step S214). In step S215, n is incremented by one, and the process returns to step S205.

An LDPC code corresponding to the mask matrix created by the processing shown in FIG. 38 exhibits a high resistance to a composite error of a burst error and a random error while, for example, almost maintaining performance such as the calculation amount and memory utilization in decoding processing as compared to the LDPC codes corresponding to the mask matrices according to the first and second comparative examples.

In step S201 of FIG. 38, the number of iterated decoding processes necessary to correct a burst error over L columns can be adjusted. For this reason, the LDPC code corresponding to the mask matrix created by the processing shown in FIG. 38 can reduce the number of iterated decoding processes necessary to correct the burst error over L columns as compared to the LDPC code corresponding to the mask matrix of the first comparative example.

In step S208 of FIG. 38, when a plurality of candidates exist, a candidate that minimizes the number of generated loops 4 is selected. For this reason, the mask matrix created by the processing shown in FIG. 38 can reduce the number of generated loops 4 as compared to the mask matrix of the first comparative example. Even if generation of loops 4 is unavoidable in the mask matrix, generation of loops 4 can be suppressed on a bit basis by adjusting the shift amounts of cyclic permutation matrices in a parity check matrix corresponding to four elements associated with each loop 4. More specifically, adjustment is done such that all the shift amounts of cyclic permutation matrices corresponding to four elements associated with each loop 4 have the same value. That is, shift amounts given to at least two of four elements are made different from each other.

When cyclic permutation matrices (shift amounts are adjustable) or zero matrices are arranged in accordance with the elements of the mask matrix created by the processing shown in FIG. 38, a parity check matrix can be created.

A simulation of the resistance of the LDPC code corresponding to the parity check matrix created by the parity check matrix creation method according to this embodiment to a composite error of a random error and a burst error will be described below. In this simulation, a model shown in FIG. 40 is employed.

As shown in FIG. 40, user data is LDPC-encoded. White Gaussian noise (corresponding to a random error) and a burst erasure signal (corresponding to a burst error) are added to the encoded data, thereby creating a reception signal. The reception signal is LDPC-decoded based on the Min-Sum decoding method. The decoded data is compared with the user data, thereby calculating an error rate.

In this simulation, the ratio of transmission energy of the transmission signal per bit to noise power is expressed using an SNR (Signal-to-Noise Ratio) given by

$$SNR [ dB ] = {log}_{10} \frac{1}{2 {σ}^{2}} \qquad ( 23 )$$

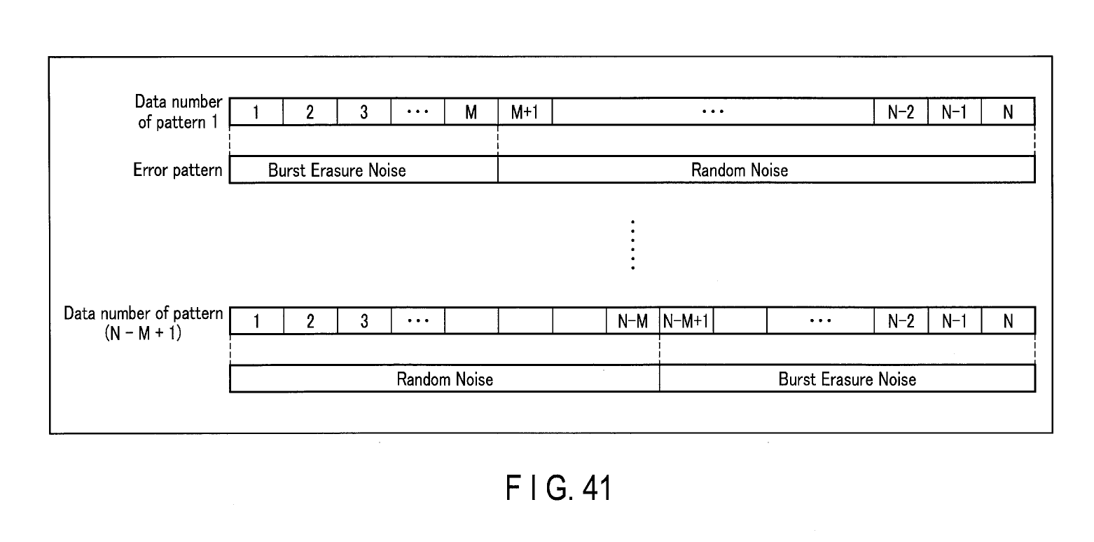

The number of burst erasure signals to be generated is set to one per codeword. In addition, as shown in FIG. 41, a simulation is performed for all burst erasure signal generation patterns. In the simulation, the burst erasure signal length is set to 1,100 bits.

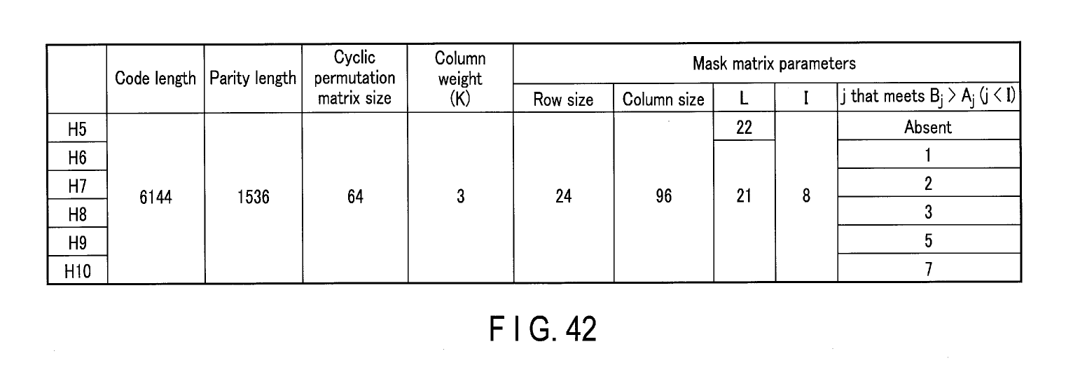

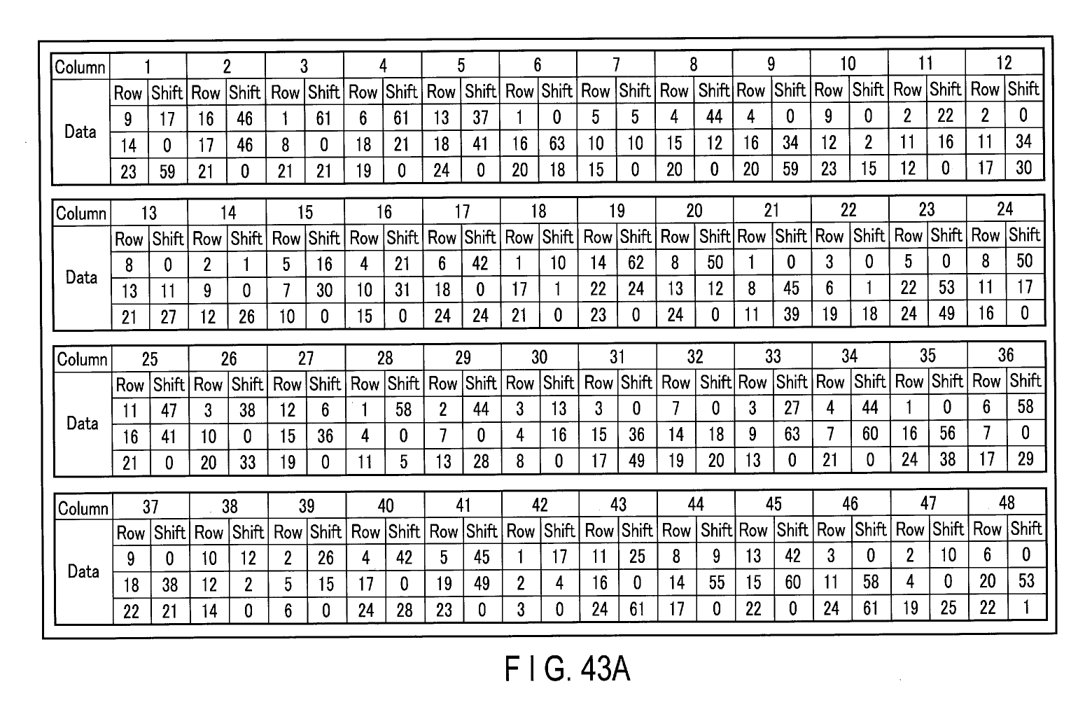

The simulation was conducted for six parity check matrices shown in FIG. 42. In all of the six parity check matrices, the codeword length is set to 6,144 bits, the parity length is set to 1,536 bits, the cyclic permutation matrix size (that is, P) is set to 64 bits, the column weight (that is, K) is set to 3, the row size of the mask matrix (that is, M) is set to 24, the column size of the mask matrix (that is, N) is set to 96, and I is set to 8.

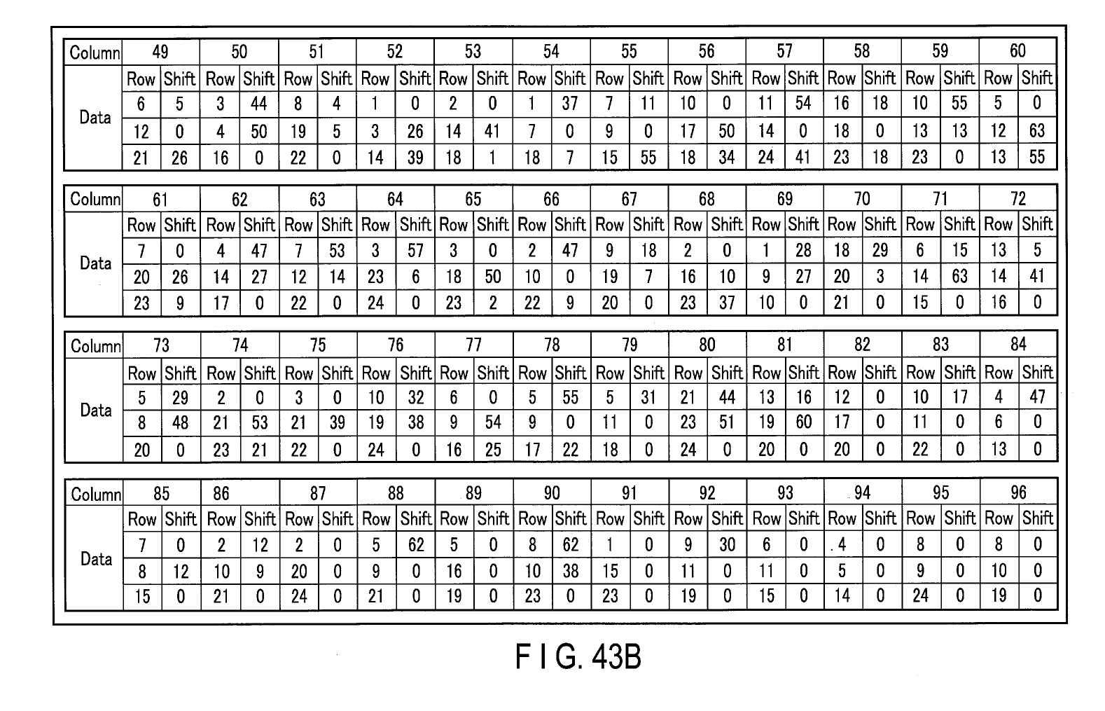

A parity check matrix corresponding to a parity check matrix (H5) is shown in FIGS. 43A and 43B. Note that in FIGS. 43A, 43B, 44A, 44B, 45A, 45B, 46A, 46B, 47A, 47B, 48A, and 48B, three row numbers at which the elements “1” are arranged (that is, row numbers at which cyclic permutation matrices each having 64 rows×64 columns are arranged) and the shift amounts of corresponding cyclic permutation matrices are specified in each column of the mask matrix.

For example, as shown in FIG. 43A, in the parity check matrix (H5), a cyclic permutation matrix shifted rightward by 17 bits is arranged in the first to 64th columns of the 513th to 576th rows corresponding to the first column of the ninth row of the mask matrix. Similarly, as shown in FIG. 43A, in the parity check matrix (H5), a cyclic permutation matrix without shift is arranged in the first to 64th columns of the 833rd to 896th rows corresponding to the first column of the 14th row of the mask matrix.

The parity check matrix (H5) is set to S=0 and L=22. Note that I (=8) is smaller than L/2 (=11). Hence, according to the parity check matrix (H5), a burst error over L columns can be corrected by a smaller number of processes as compared to the parity check matrix of the first comparative example. In addition, since S=0, the condition (g) is not met.

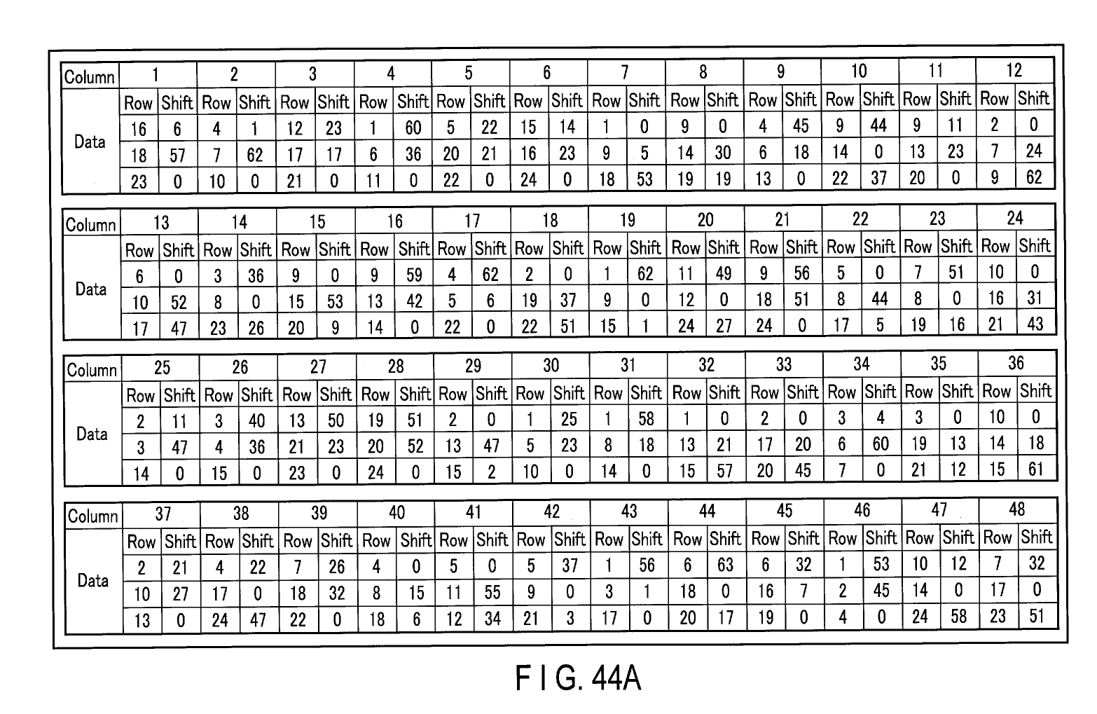

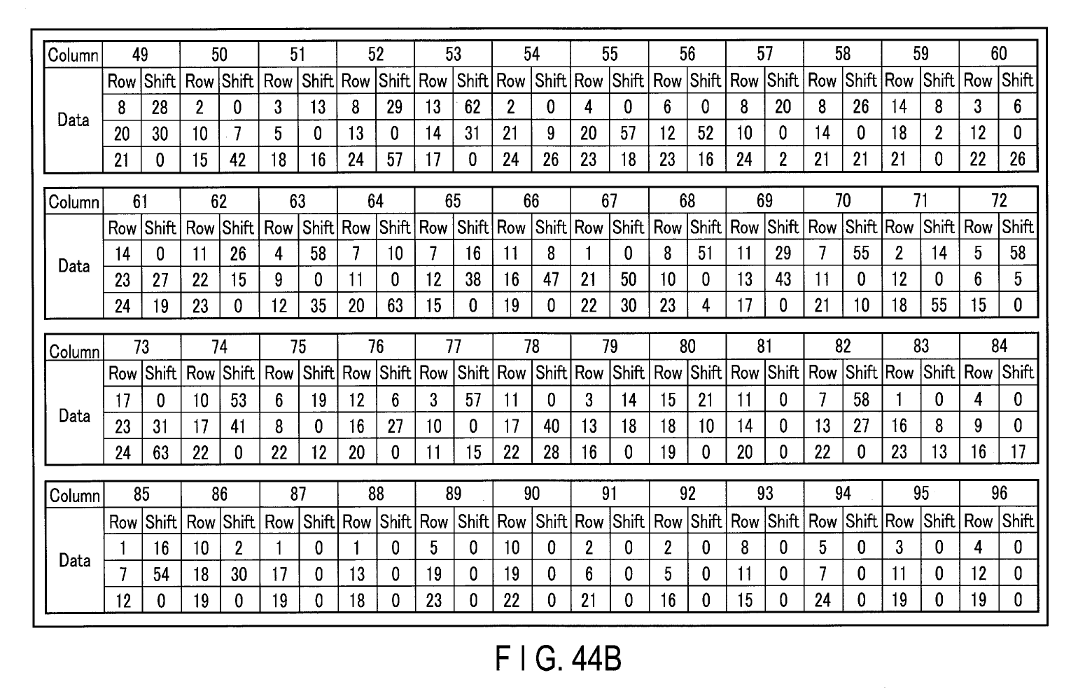

A parity check matrix (H6) is shown in FIGS. 44A and 44B. The parity check matrix (H6) is set to S=1 and L=21. Note that I (=8) is smaller than L/2 (=10.5). Hence, according to the parity check matrix (H6), a burst error over L columns can be corrected by a smaller number of processes as compared to the parity check matrix of the first comparative example. Additionally, in the parity check matrix (H6), j=1. That is, the number B₁ of first correction rows is larger than the number A₁ of first correction columns.

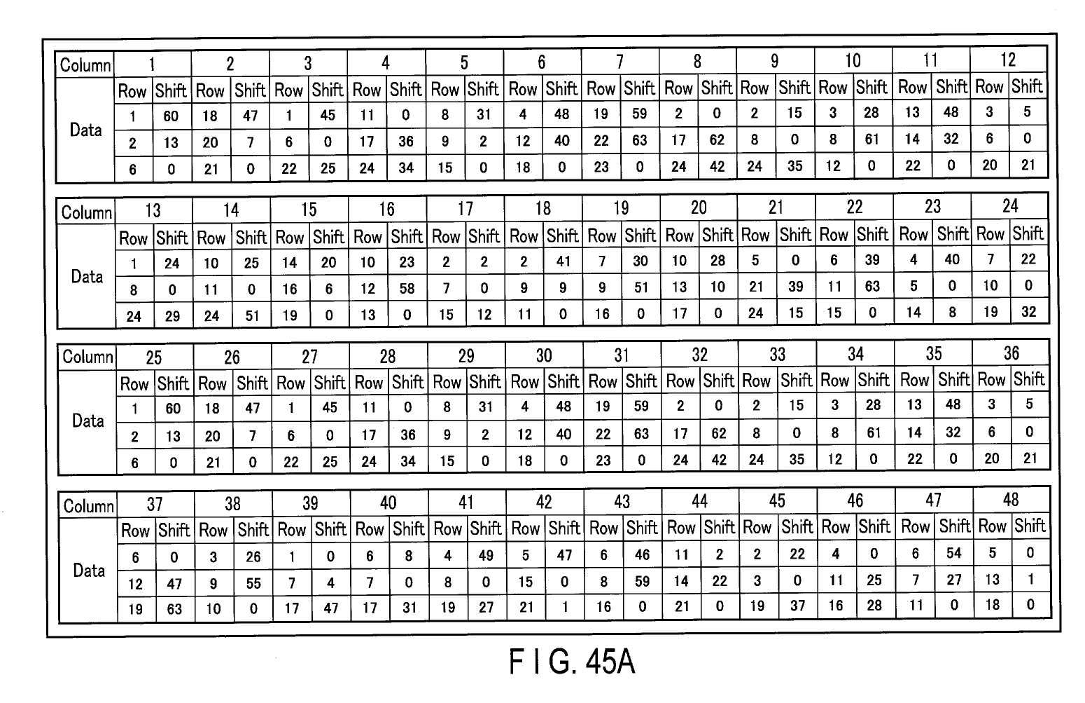

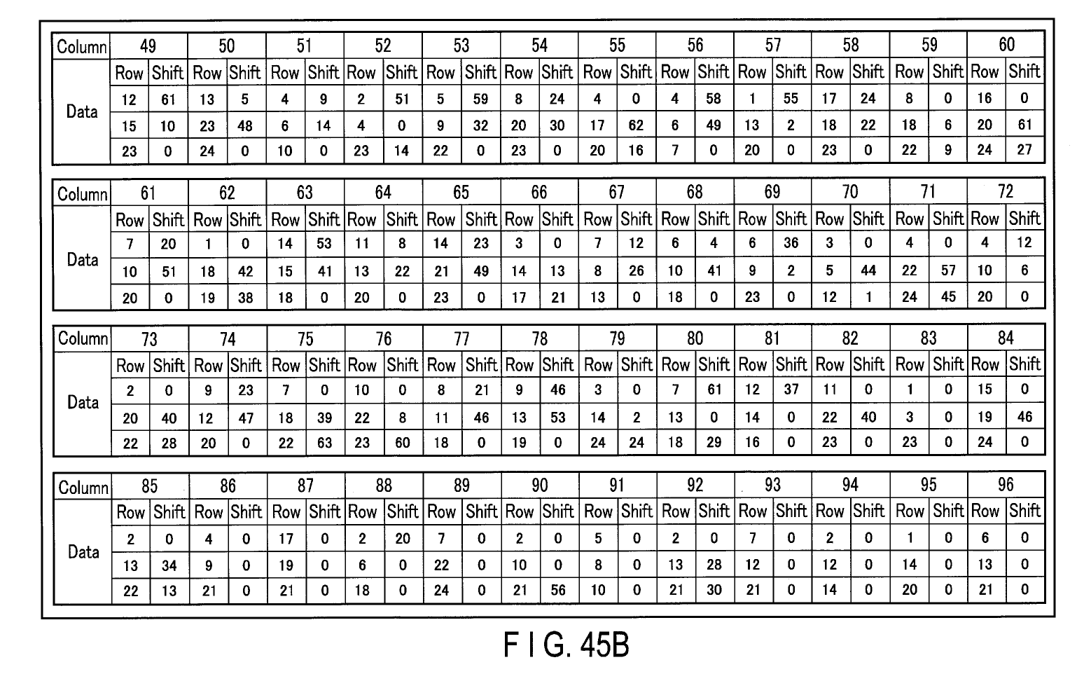

A parity check matrix (H7) is shown in FIGS. 45A and 45B. The parity check matrix (H7) is set to S=1 and L=21. Note that I (=8) is smaller than L/2 (=10.5). Hence, according to the parity check matrix (H7), a burst error over L columns can be corrected by a smaller number of processes as compared to the parity check matrix of the first comparative example. Additionally, in the parity check matrix (H7), j=2. That is, the number B₂ of second correction rows is larger than the number A₂ of second correction columns.

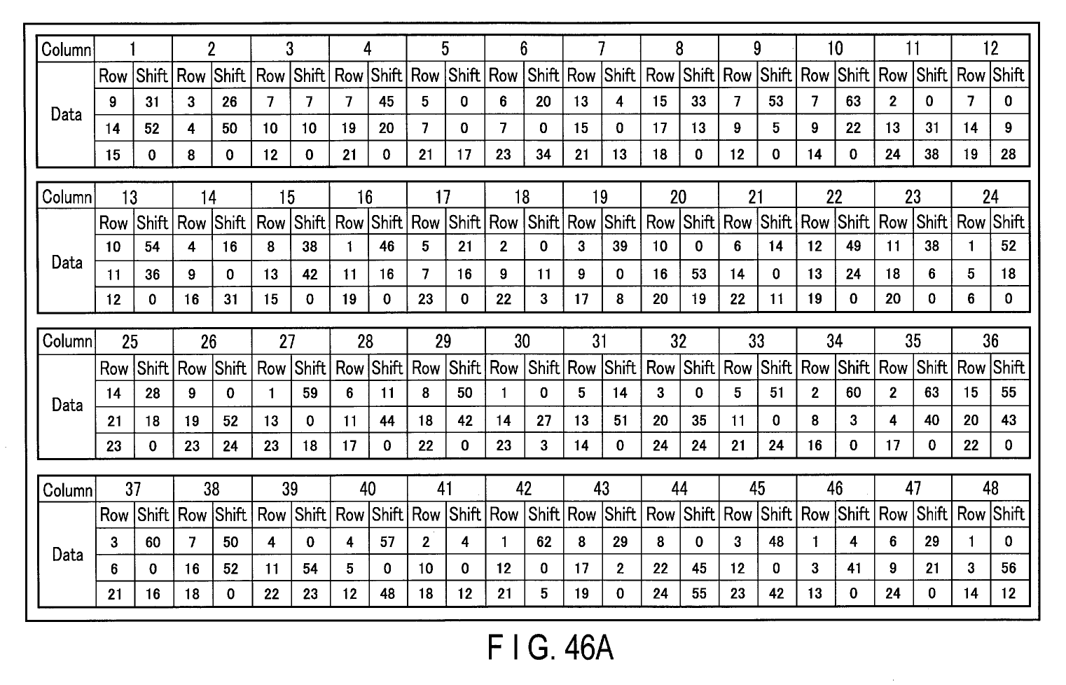

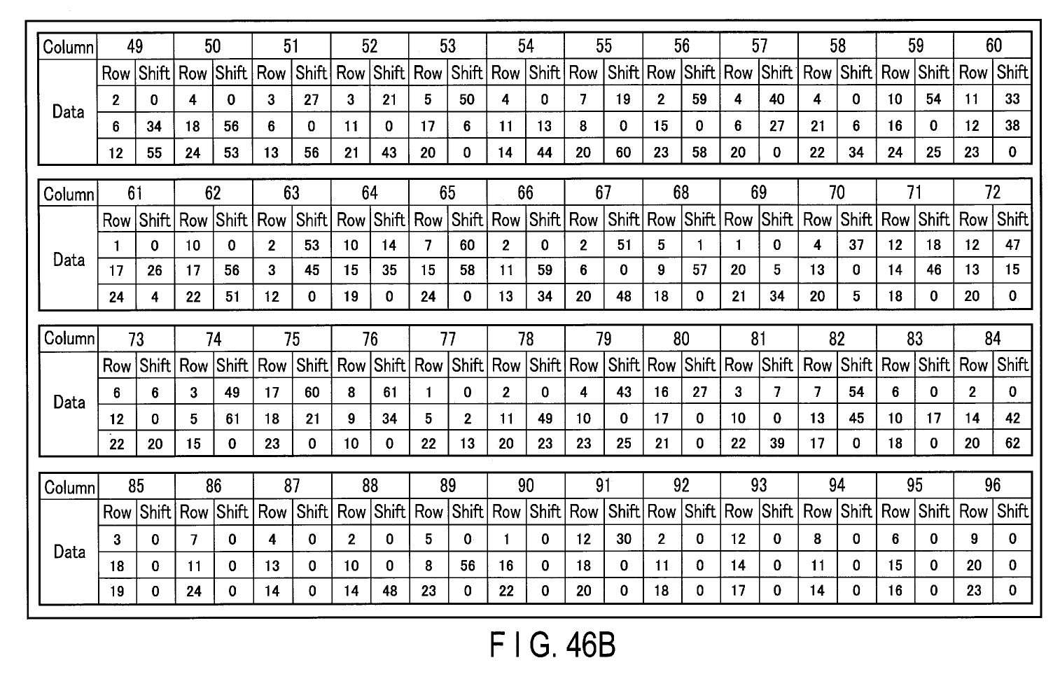

A parity check matrix (H8) is shown in FIGS. 46A and 46B. The parity check matrix (H8) is set to S=1 and L=21. Note that I (=8) is smaller than L/2 (=10.5). Hence, according to the parity check matrix (H8), a burst error over L columns can be corrected by a smaller number of processes as compared to the parity check matrix of the first comparative example. Additionally, in the parity check matrix (H8), j=3. That is, the number B₃ of third correction rows is larger than the number A₃ of third correction columns.

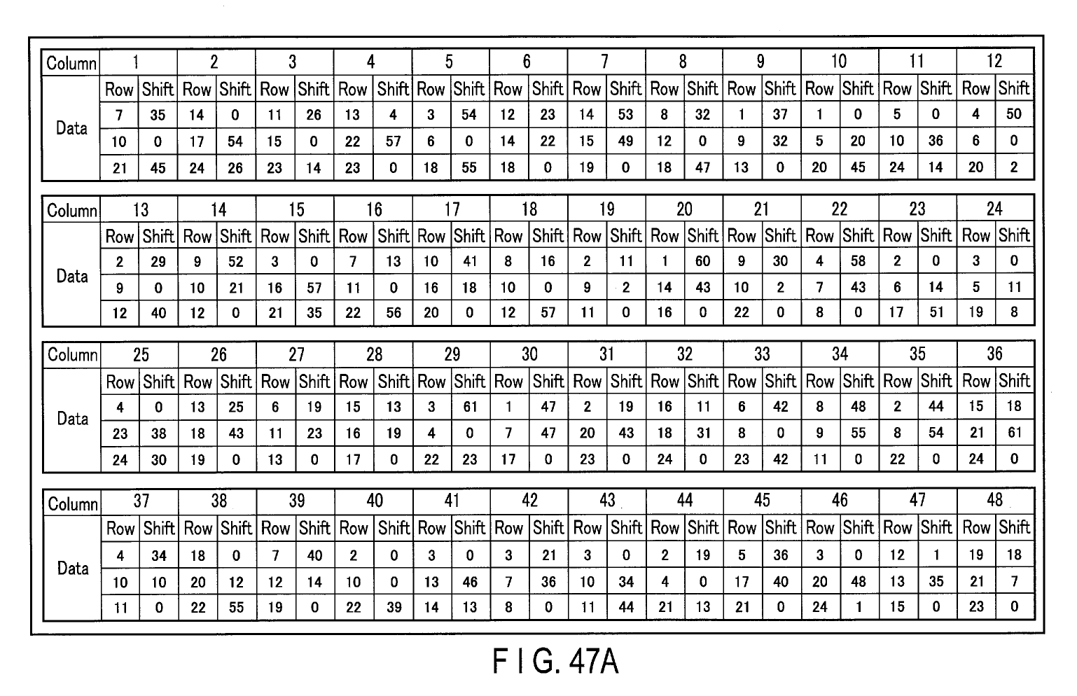

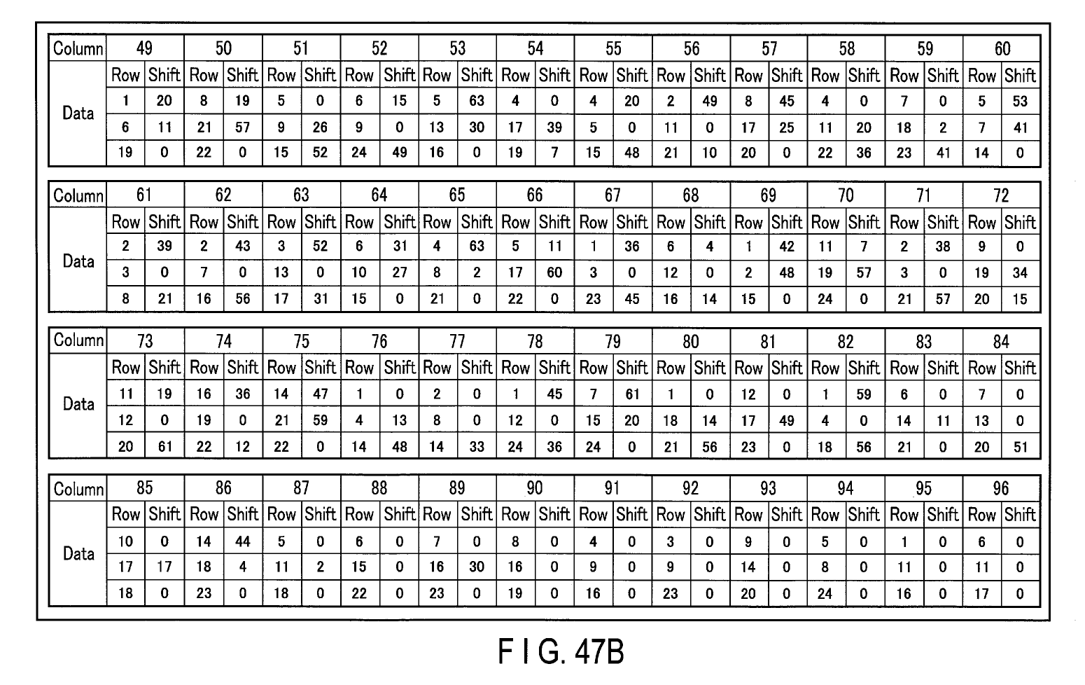

A parity check matrix (H9) is shown in FIGS. 47A and 47B. The parity check matrix (H9) is set to S=1 and L=21. Note that I (=8) is smaller than L/2 (=10.5). Hence, according to the parity check matrix (H9), a burst error over L columns can be corrected by a smaller number of processes as compared to the parity check matrix of the first comparative example. Additionally, in the parity check matrix (H9), j=5. That is, the number B₅ of fifth correction rows is larger than the number A₅ of fifth correction columns.

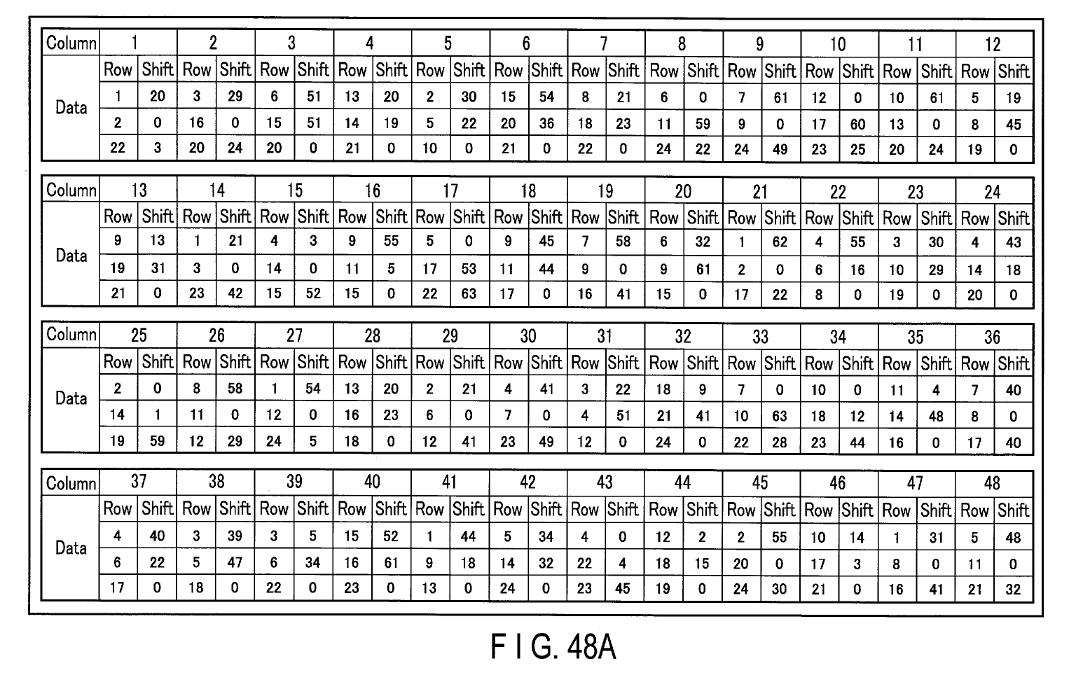

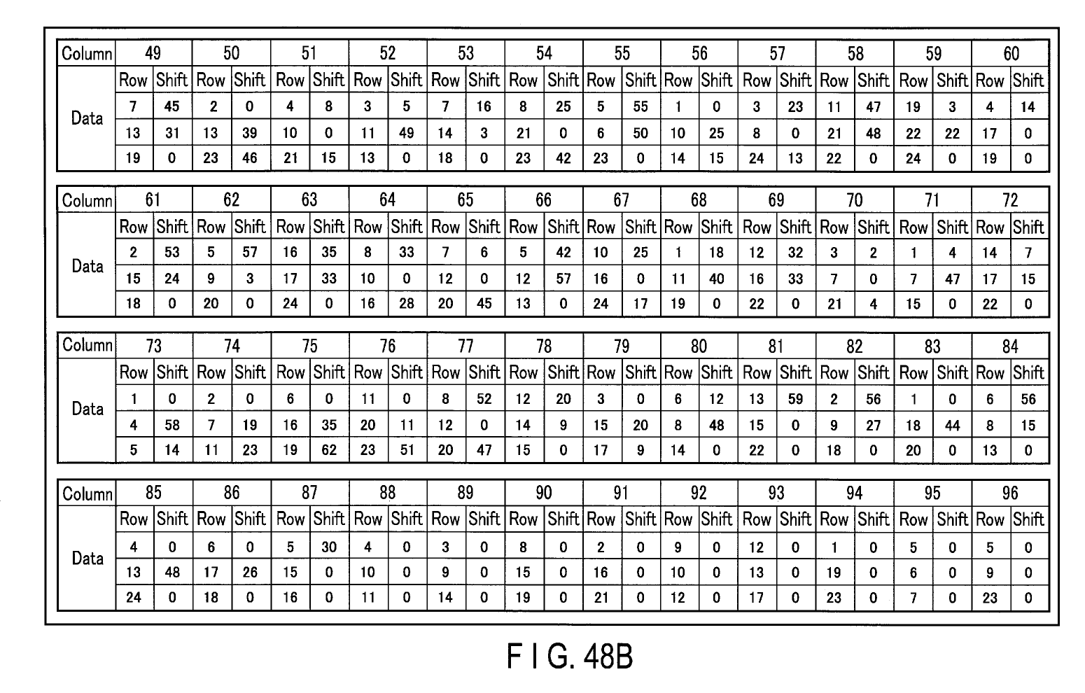

A parity check matrix (H10) is shown in FIGS. 48A and 48B. The parity check matrix (H10) is set to S=1 and L=21. Note that I (=8) is smaller than L/2 (=10.5). Hence, according to the parity check matrix (H10), a burst error over L columns can be corrected by a smaller number of processes as compared to the parity check matrix of the first comparative example. Additionally, in the parity check matrix (H10), j=7. That is, the number B₇ of seventh correction rows is larger than the number A₇ of seventh correction columns.

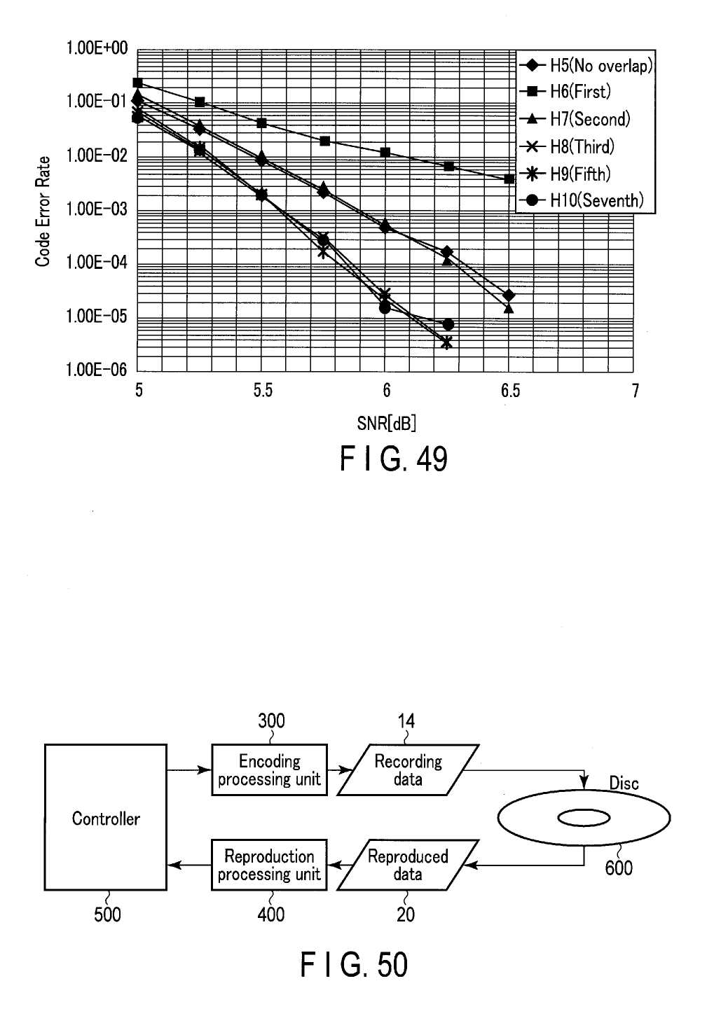

FIG. 49 shows the simulation result of LDPC codes corresponding to the six parity check matrices. In the simulation shown in FIG. 49, LDPC decoding is performed for reception signals with white Gaussian noise of different levels added 50 times for each data missing pattern.

In FIG. 49, the ordinate represents the error rate. A low error rate indicates an excellent error correction result. In FIG. 49, the abscissa represents SNR [dB]. A low SNR indicates large power of white Gaussian noise, that is, a poor reception environment.

According to FIG. 49, the parity check matrix (H6) and the parity check matrix (H7) can be evaluated to have a resistance almost equal to or lower than that of the parity check matrix (H5) to a composite error of a burst error and a random error. On the other hand, the parity check matrix (H8), the parity check matrix (H9), and the parity check matrix (H10) can be evaluated to have a resistance higher than that of the parity check matrix (H5) to a composite error of a burst error and a random error. That is, the effectiveness of this embodiment was confirmed in the parity check matrix (H8), the parity check matrix (H9), and the parity check matrix (H10). Hence, it can be found out that j is preferably set to 3 or more at least in a situation equal or similar to the simulation condition.

As described above, the parity check matrix creation method according to the first embodiment includes creating a mask matrix such that in a submatrix obtained by arbitrarily extracting L continuous columns from the mask matrix, the total number of rows from the first correction row to the (I−1)th correction row equals the sum of the total number of columns from the first correction column to the (I−1)th correction column and S (S is an integer of 1 or more). That is, in this submatrix, the number of jth correction rows is larger than the number of jth correction columns (j is at least one integer from 1 to (I−1)). Hence, according to this parity check matrix creation method, it is possible to expect the effect of correcting, by propagation processing of the jth time, a wrong correction result generated by correction processing of the jth time. It is also possible to expect the effect of correcting a wrong correction result generated in the past before the jth time by correction processing and propagation processing in the future included in the burst error correction phase.

### Second Embodiment

A parity check matrix created by the parity check matrix creation method according to the first embodiment is used for error correction decoding processing by a decoding apparatus. In addition, this parity check matrix is used for error correction encoding processing by an encoding apparatus in a state in which the parity check matrix is converted into, for example, a generator matrix. The encoding apparatus and the decoding apparatus are incorporated in, for example, a recording/reproduction system or a communication system.

A recording/reproduction apparatus according to the second embodiment includes an encoding apparatus and a decoding apparatus for error correction. The encoding apparatus and the decoding apparatus use a parity check matrix created by the parity check matrix creation method according to the first embodiment. Note that this parity check matrix can be used by all systems to which an error correcting code is applied, for example, a semiconductor memory device, a communication apparatus, or a magnetic recording/reproduction apparatus, although a detailed description will be omitted.

As shown in FIG. 50, the recording/reproduction apparatus according to this embodiment includes an encoding processing unit 300, a reproduction processing unit 400, and a controller 500. The recording/reproduction apparatus creates recording data 14 from user data and writes it in an optical recording medium 600, or processes reproduced data 20 obtained from the optical recording medium 600 and reconstructs the user data. The controller 500 controls the functional units of the encoding processing unit 300 and the reproduction processing unit 400 to be described later. The encoding processing unit 300 creates the recording data 14 in accordance with an instruction from the controller 500. The reproduction processing unit 400 processes the reproduced data 20 in accordance with an instruction from the controller 500.

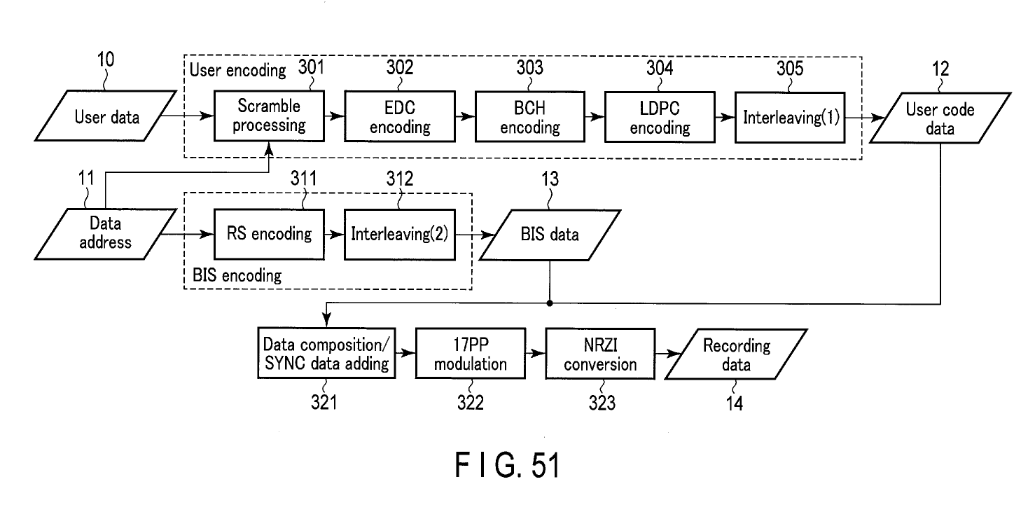

As shown in FIG. 51, the encoding processing unit 300 includes a scramble processing unit 301, an EDC (Error Detection Code) encoding unit 302, a BCH encoding unit 303, an LDPC encoding unit 304, a first interleaving unit 305, an RS (Reed-Solomon) encoding unit 311, a second interleaving unit 312, a data composition/SYNC data adding unit 321, a 17PP (Parity Preserve/Prohibit) modulation unit 322, and an NRZI (Non Return to Zero Inversion) conversion unit 323.

The encoding processing unit 300 receives user data 10 and a data address 11 from the controller 500. The encoding processing unit 300 creates user code data 12 by encoding the data address 11, creates BIS (Burst Indicator SubCode) data 13 by encoding the data address 11, and creates the recording data 14 based on the user code data 12 and the

BIS data 13. Note that the BIS data 13 is used to detect a burst error, as will be described later.

The scramble processing unit 301 receives the user data 10 and the data address 11 from the controller 500. The scramble processing unit 301 performs scramble processing for the user data 10 based on the data address 11, thereby obtaining scrambled user data. The scramble processing unit 301 outputs the scrambled data to the EDC encoding unit 302.

The EDC encoding unit 302 receives the scrambled data from the scramble processing unit 301. The EDC encoding unit 302 performs EDC encoding for the scrambled data, thereby obtaining EDC encoded data. The EDC encoding unit 302 outputs the EDC encoded data to the BCH encoding unit 303.

The BCH encoding unit 303 receives the EDC encoded data from the EDC encoding unit 302. The BCH encoding unit 303 performs BCH encoding for the EDC encoded data, thereby obtaining BCH encoded data. The BCH encoding unit 303 outputs the BCH encoded data to the LDPC encoding unit 304.

The LDPC encoding unit 304 uses a parity check matrix created by the parity check matrix creation method according to the first embodiment in a state in which the parity check matrix is converted into, for example, a generator matrix. The LDPC encoding unit 304 receives the BCH encoded data from the BCH encoding unit 303. The LDPC encoding unit 304 performs LDPC encoding based on the parity check matrix for the BCH encoded data, thereby obtaining LDPC encoded data. The LDPC encoding unit 304 outputs the LDPC encoded data to the first interleaving unit 305.

The first interleaving unit 305 receives the LDPC encoded data from the LDPC encoding unit 304. The first interleaving unit 305 performs interleaving for the LDPC encoded data, thereby obtaining the user code data 12. The first interleaving unit 305 outputs the user code data 12 to the data composition/SYNC data adding unit 321.

The RS encoding unit 311 receives the data address 11 from the controller 500. The RS encoding unit 311 performs RS encoding for the data address 11, thereby obtaining RS encoded data. The RS encoding unit 311 outputs the RS encoded data to the second interleaving unit 312.

The second interleaving unit 312 receives the RS encoded data from the RS encoding unit 311. The second interleaving unit 312 performs interleaving for the RS encoded data, thereby obtaining the BIS data 13. The second interleaving unit 312 outputs the BIS data 13 to the data composition/SYNC data adding unit 321.

The data composition/SYNC data adding unit 321 receives the user code data 12 from the first interleaving unit 305 and the BIS data 13 from the second interleaving unit 312. The data composition/SYNC data adding unit 321 composes the user code data 12 and the BIS data 13 and adds SYNC data, thereby generating composed data. The SYNC data is used to detect the start of corresponding composed data. The data composition/SYNC data adding unit 321 outputs the composed data to the 17PP modulation unit 322.

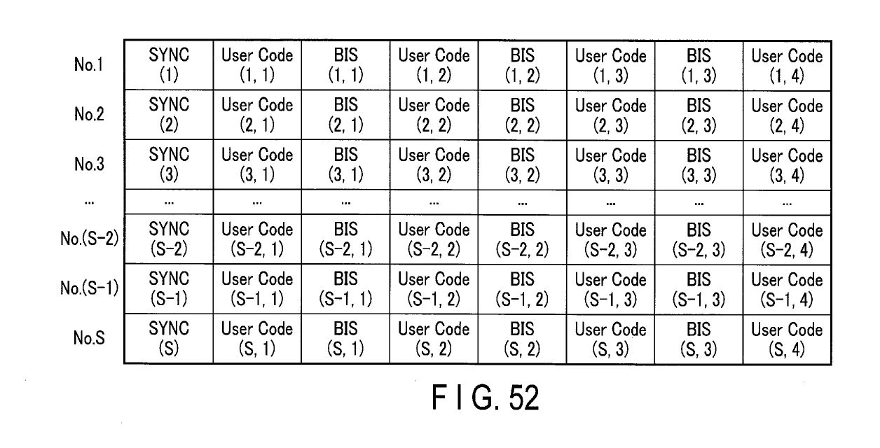

More specifically, the data composition/SYNC data adding unit 321 generates composed data in accordance with a format shown in FIG. 52. According to FIG. 52, SYNC data is arranged at the start of composed data of one unit. The composed data of one unit corresponds to one recording frame. Next to the SYNC data, the user code data 12 having a fixed length and the BIS data 13 corresponding to one symbol of the RS code are alternately arranged. In other words, four fields having a fixed size are prepared for the user code data 12 in the composed data of one unit. BIS data corresponding to one symbol of the RS code is inserted between adjacent fields.

The 17PP modulation unit 322 receives the composed data from the data composition/SYNC data adding unit 321. The 17PP modulation unit 322 performs RLL (Run Length Limited) encoding for the composed data using a 17PP modulation code that is the modulation code of the Blu-ray method known as an optical disc standard, thereby obtaining RLL encoded data. The 17PP modulation unit 322 outputs the RLL encoded data to the NRZI conversion unit 323.

The NRZI conversion unit 323 receives the RLL encoded data from the data composition/SYNC data adding unit 321. The NRZI conversion unit 323 performs NRZI conversion for the RLL encoded data, thereby obtaining the recording data 14.

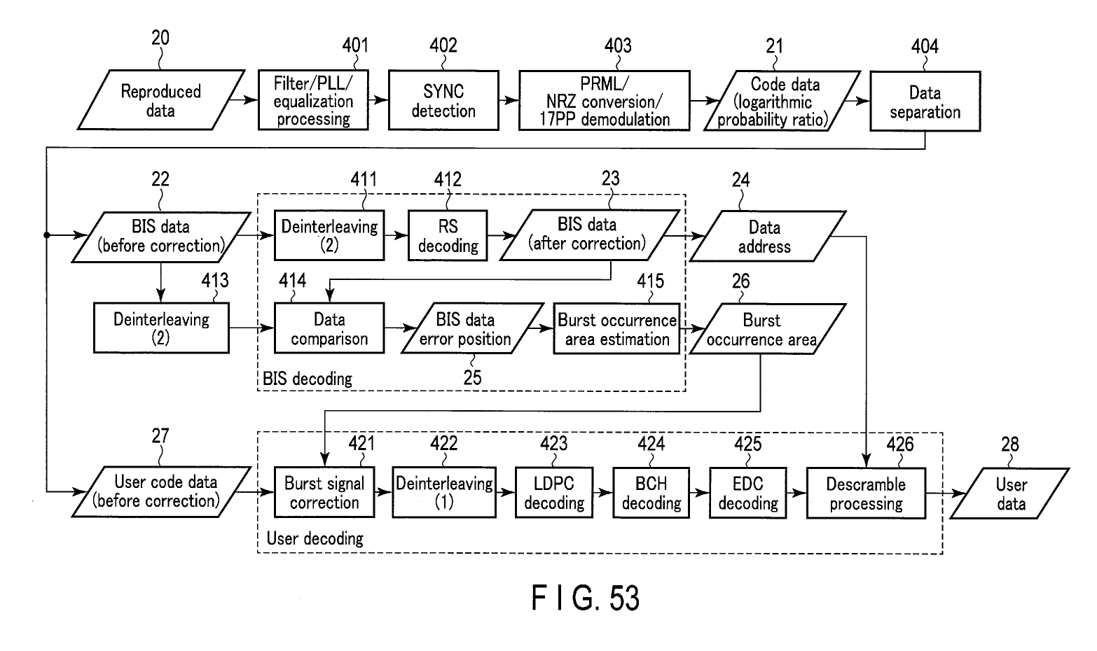

As shown in FIG. 53, the reproduction processing unit 400 includes a filter/PLL/equalization processing unit 401, a SYNC detection unit 402, a PRML/NRZ conversion/17PP demodulation unit 403, a data separation unit 404, a second deinterleaving unit 411, an RS decoding unit 412, a second deinterleaving unit 413, a data comparison unit 414, a burst occurrence area estimation unit 415, a burst signal correction unit 421, a first deinterleaving unit 422, an LDPC decoding unit 423, a BCH decoding unit 424, an EDC decoding unit 425, and a descramble processing unit 426.

The reproduction processing unit 400 receives the reproduced data 20 from the optical recording medium 600 and performs various processes to be described later for the reproduced data 20, thereby restoring user data 28.

The filter/PLL/equalization processing unit 401 receives the reproduced data 20 from the optical recording medium 600. The filter/PLL/equalization processing unit 401 performs signal processing including filter processing, PLL (Phase Locked Loop) processing and equalization processing, thereby obtaining equalized data. The filter/PLL/equalization processing unit 401 outputs the equalized data to the SYNC detection unit 402.

The SYNC detection unit 402 detects SYNC data from the equalized data in accordance with, for example, the format shown in FIG. 52. The SYNC detection unit 402 performs synchronization processing of the recording frame based on the detected SYNC data. The SYNC detection unit 402 outputs the synchronized data to the PRML/NRZ conversion/17PP demodulation unit 403.

The PRML/NRZ conversion/17PP demodulation unit 403 receives the synchronized data from the SYNC detection unit 402. The PRML/NRZ conversion/17PP demodulation unit 403 performs PRML processing, NRZ conversion, and 17PP demodulation for the synchronized data, thereby obtaining code data 21. The code data 21 corresponds to the logarithmic probability ratio of user code data and the logarithmic probability ratio of BIS data. The PRML/NRZ conversion/17PP demodulation unit 403 outputs the code data 21 to the data separation unit 404.

The data separation unit 404 receives the code data 21 from the PRML/NRZ conversion/17PP demodulation unit 403. The data separation unit 404 separates the code data 21, thereby obtaining BIS data 22 and user code data 27. The BIS data 22 corresponds to the logarithmic probability ratio of BIS data. The user code data 27 corresponds to the logarithmic probability ratio of user code data. The data separation unit 404 outputs the BIS data 22 to the second deinterleaving units 411 and 413. The data separation unit 404 outputs the user code data 27 to the burst signal correction unit 421.

The second deinterleaving unit 411 receives the BIS data 22 from the data separation unit 404. The second deinterleaving unit 411 performs deinterleaving for the BIS data 22, thereby obtaining deinterleaved BIS data. The second deinterleaving unit 411 outputs the deinterleaved BIS data to the RS decoding unit 412.

The RS decoding unit 412 receives the deinterleaved BIS data from the second deinterleaving unit 411. The RS decoding unit 412 performs RS decoding for the deinterleaved BIS data, thereby obtaining BIS data 23. Note that the BIS data 23 corresponds to a data address 24. The RS decoding unit 412 outputs the BIS data 23 to the data comparison unit 414. The RS decoding unit 412 also outputs the data address 24 to the descramble processing unit 426.

The second deinterleaving unit 413 receives the BIS data 22 from the data separation unit 404. The second deinterleaving unit 413 performs the same deinterleaving as that of the second deinterleaving unit 411 for the BIS data 22, thereby obtaining deinterleaved BIS data. The second deinterleaving unit 413 outputs the deinterleaved BIS data to the data comparison unit 414.

The data comparison unit 414 receives the BIS data 23 from the RS decoding unit 412 and the deinterleaved BIS data from the second deinterleaving unit 413. The data comparison unit 414 compares the BIS data 23 with the deinterleaved BIS data, thereby determining an error included in the deinterleaved BIS data. As the result of determination, the data comparison unit 414 obtains BIS data error position information 25. As described above, the BIS data 23 is generated by performing RS decoding for the deinterleaved BIS data. Hence, when the two pieces of data are compared, an error included in the deinterleaved BIS data can be determined. The data comparison unit 414 outputs the BIS data error position information 25 to the burst occurrence area estimation unit 415.

The burst occurrence area estimation unit 415 receives the BIS data error position information 25 from the data comparison unit 414. The burst occurrence area estimation unit 415 estimates the occurrence area of a burst error in the user code data based on the BIS data error position information 25, thereby obtaining burst occurrence area information 26. The burst occurrence area estimation unit 415 outputs the burst occurrence area information 26 to the burst signal correction unit 421. Note that the burst occurrence area estimation unit 415 may estimate the occurrence area of a burst error in the user code data based on the information of the presence/absence of an error of SYNC data in addition to the BIS data error position.

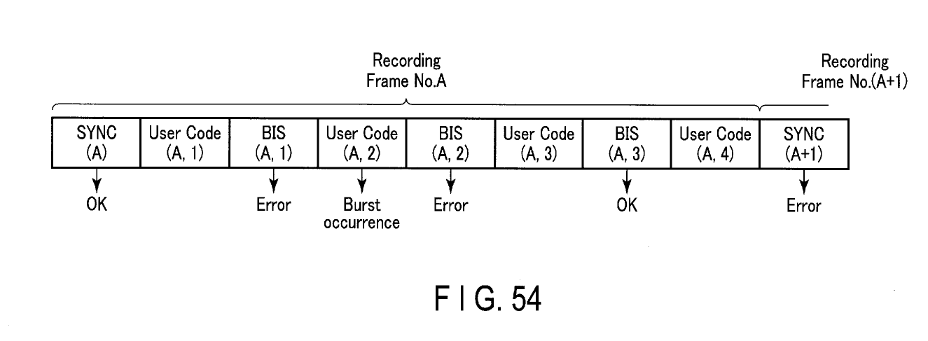

For example, assume that, as shown in FIG. 54, SYNC data (SYNC (A)) and third BIS data (BIS (A, 3)) are correct, and first and second BIS data (BIS (A, 1) and BIS (A, 2)) are wrong in the Ath recording frame. When a burst error is assumed to have occurred, second user code data (A, 2) arranged between the first and second BIS data is wrong at a high possibility. For this reason, according to the example of FIG. 54, the burst occurrence area estimation unit 415 estimates the second user code data as a burst occurrence area.

The burst signal correction unit 421 receives the burst occurrence area information 26 from the burst occurrence area estimation unit 415 and the user code data 27 from the data separation unit 404. The burst signal correction unit 421 specifies the burst occurrence area in the user code data 27 based on the burst occurrence area 26. The burst signal correction unit 421 corrects the logarithmic probability ratio of bits corresponding to the burst occurrence area out of the user code data 27 to, for example, 0, thereby obtaining corrected user code data. Logarithmic probability ratio=0 means that the probability that a corresponding bit is 0 and the probability that the bit is 1 are equal. According to this correction, it is possible to prevent a wrong logarithmic probability ratio in the burst occurrence area from having an adverse effect outside the burst occurrence area in LDPC decoding to be performed by the LDPC decoding unit 423. The burst signal correction unit 421 outputs the corrected user code data to the first deinterleaving processing unit 422.

The first deinterleaving processing unit 422 receives the corrected user code data from the burst signal correction unit 421. The first deinterleaving processing unit 422 performs deinterleaving for the corrected user code data, thereby obtaining deinterleaved user code data. The first deinterleaving processing unit 422 outputs the deinterleaved user code data to the LDPC decoding unit 423.

The LDPC decoding unit 423 uses a parity check matrix created by the parity check matrix creation method according to the first embodiment. The LDPC decoding unit 423 receives the deinterleaved user code data from the first deinterleaving processing unit 422. The LDPC decoding unit 423 performs LDPC decoding based on the parity check matrix for the deinterleaved user code data, thereby obtaining LDPC decoded data. The LDPC decoding unit 423 outputs the LDPC decoded data to the BCH decoding unit 424.

The BCH decoding unit 424 receives the LDPC decoded data from the LDPC decoding unit 423. The BCH decoding unit 424 performs BCH decoding for the LDPC decoded data, thereby obtaining BCH decoded data. The BCH decoding unit 424 outputs the BCH decoded data to the EDC decoding unit 425.

The EDC decoding unit 425 receives the BCH decoded data from the BCH decoding unit 424. The BCH decoding unit 425 performs EDC decoding for the BCH decoded data, thereby obtaining EDC decoded data. The EDC decoding unit 425 outputs the EDC decoded data to the descramble processing unit 426.

The descramble processing unit 426 receives the data address 24 from the RS decoding unit 412 and the EDC decoded data from the EDC decoding unit 425. The descramble processing unit 426 performs descramble processing for the EDC decoded data based on the data address 24, thereby obtaining the user data 28. The descramble processing unit 426 outputs the user data 28 to the controller 500.

As described above, the recording/reproduction apparatus according to the second embodiment performs LDPC encoding and LDPC decoding based on a parity check matrix created by the parity check matrix creation method according to the first embodiment. Hence, according to this recording/reproduction apparatus, it is possible to stably reproduce data even when a composite error of a burst error and a random error has occurred.

The processing in the above-described embodiments can be implemented using a general-purpose computer as basic hardware. A program implementing the processing in each of the above-described embodiments may be stored in a computer readable storage medium for provision. The program is stored in the storage medium as a file in an installable or executable format. The storage medium is a magnetic disk, an optical disc (CD-ROM, CD-R, DVD, or the like), a magnetooptic disc (MO or the like), a semiconductor memory, or the like. That is, the storage medium may be in any format provided that a program can be stored in the storage medium and that a computer can read the program from the storage medium. Furthermore, the program implementing the processing in each of the above-described embodiments may be stored on a computer (server) connected to a network such as the Internet so as to be downloaded into a computer (client) via the network.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A parity check matrix creation method comprising:
creating a mask matrix whose column weight is K (K is an integer not less than 2) by assigning one of “1” and “0” to each element of M rows×N columns (M is an integer not less than 4, and N is an integer larger than M); and
creating a parity check matrix by, for each element in the mask matrix, arranging a cyclic permutation matrix having P rows×P columns (P is an integer not less than 2) at a corresponding position when the element is “1” and arranging a zero matrix having P rows×P columns at a corresponding position when the element is “0”,
wherein all of N column vectors in the mask matrix are different from each other,
a submatrix having M rows×L columns (L is an integer not more than (M−K+1−S) and S is an integer not less than 1) obtained by arbitrarily extracting L continuous columns from the mask matrix includes:
B₁ (B₁ is an integer not less than 1) first correction rows; and
Bᵢ (Bᵢ is an integer not less than 1, i is any integer not less than 2 and not more than I, and I is an integer not less than 2) ith correction rows,
each of the B₁ first correction rows has a row weight of 1,
the B₁ first correction rows have at least one “1” in total in each of A₁ (A₁ is an integer not less than 1) first correction columns,
each of the Bᵢ ith correction rows has a row weight of not less than 2,
each of the Bᵢ ith correction rows has at least one “1” in total in Aᵢ₋₁ (Aᵢ₋₁ is an integer not less than 1 and not more than Bᵢ₋₁) (i−1)th correction columns,
each of the B₁ ith correction rows has “1” in one of Aᵢ (Aᵢ is an integer not less than 1 and not more than Bᵢ) ith correction columns included in a column set excluding the first correction column to the (i−1)th correction column,
the Bᵢ ith correction rows include at least one “1” in total in each of the Aᵢ ith correction columns,
a sum from A₁ to A_{I} equals L,
Bᵢ is not more than Aᵢ₋₁×(K−1), and
a sum from B₁ to B_{I-1} equals a sum of S and a sum from A₁ to A_{I-1}.

2. The method according to claim 1, wherein A_{I} equals 1, B_{I} equals K, and L equals M−K+1−S.

3. The method according to claim 1, wherein A_{I} is not less than 2,
the submatrix further includes at least one Ith propagation row,
each of the at least one propagation row has at least two “1”s in total in the A_{I} Ith correction columns.

4. The method according to claim 1, wherein A_{I} is not less than 2, B_{I} equals A_{I}, and L equals M−K+1−S,
the submatrix further includes (K−1) Ith propagation rows, and
each of the (K−1) Ith propagation rows has “1” in all the A_{I} Ith correction columns.

5. The method according to claim 1, wherein j that meets Aⱼ<Bⱼ is at least one integer not less than 3 and not more than (I−1).

6. The method according to claim 1, wherein each of the Aᵢ₋₁ (i−1)th correction columns has two “1”s out of “1”s belonging to Bᵢ₋₁ (i−1)th correction rows at maximum.

7. The method according to claim 1, wherein a maximum value of S is M−A_{I}−K+2−I.

8. The method according to claim 6, wherein a maximum value of S is (a sum from B₁ to B_{I-1})/2 (fractions after a decimal point are dropped).

9. The method according to claim 1, further comprising setting the value A₁, the value Aᵢ, the value B₁, and the value Bᵢ.

10. The method according to claim 1, further comprising setting the value A₁ and the value Aᵢ such that I becomes not more than L/2.

11. The method according to claim 1, further comprising setting a shift amount of a cyclic permutation matrix arranged at at least one of four positions corresponding to four elements where loops 4 are generated in the mask matrix to a first value and setting the shift amount of the cyclic permutation matrix arranged at at least one of the remaining positions to a second value different from the first value.

12. An encoding apparatus comprising an encoding unit configured to encode data based on a parity check matrix created by the method of claim 1.

13. A recording/reproduction apparatus comprising:
a first encoding unit configured to encode first data based on a parity check matrix created by the method of claim 1 to obtain first encoded data;
a second encoding unit configured to encode second data different from the first data to obtain second encoded data;
a composition unit configured to compose the first encoded data and the second encoded data to create a data frame to be recorded in a recording medium;
a first decoding unit configured to decode the second encoded data out of reproduced data of the data frame from the recording medium to obtain second decoded data;
an estimation unit configured to estimate an occurrence area of a burst error in the first encoded data out of the reproduced data based on the second decoded data;
a correction unit configured to correct a value associated with each bit corresponding to the occurrence area out of the first encoded data to a value representing that a probability that the bit is 0 and a probability that the bit is 1 are equal to obtain corrected first encoded data; and
a second decoding unit configured to decode the corrected first encoded data based on the parity check matrix to obtain first decoded data.

14. The apparatus according to claim 13, wherein the correction unit corrects the value associated with each bit corresponding to the occurrence area out of the first encoded data to “0” to obtain the corrected first encoded data.
